(19) United States
(12) Patent Application Publication
(10) Pub. No.: US 2024/0102196 A1
(43) Pub. Date: Mar. 28, 2024

(54) SYSTEMS AND METHODS FOR THINNING TRANSITION METAL DICHALCOGENIDES

(71) Applicant: BOARD OF REGENTS, THE UNIVERSITY OF TEXAS SYSTEM, Austin, TX (US)

(72) Inventors: Yuebing Zheng, Austin, TX (US); Suichu Huang, Austin, TX (US)

(21) Appl. No.: 18/036,263

(22) PCT Filed: Nov. 12, 2021
(86) PCT No.: PCT/US2021/059111

§ 371 Date: May 10, 2023

Related U.S. Application Data
(60) Provisional application No. 63/113,752, filed on Nov. 13, 2020.

(51) Int. Cl. C25F 3/08

(52) U.S. Cl. CPC C25F 3/08

(57) ABSTRACT

Disclosed herein are methods and systems for thinning a transition metal dichalcogenide. The methods comprise: illuminating the transition metal dichalcogenide material with electromagnetic radiation while applying a positive potential between the transition metal dichalcogenide material and a gate electrode; wherein the electromagnetic radiation has an energy that is less than the energy of the direct band gap and greater than or equal to the energy of the indirect band gap of the transition metal dichalcogenide material; thereby: promoting electrons from the valence band to the conduction band of the indirect band gap of the transition metal dichalcogenide material and decreasing the thickness of the transition metal dichalcogenide via electrochemical degradation. The methods disclosed herein are self-limiting. Also disclosed herein are patterned transition metal dichalcogenide materials and monolayers of transition metal dichalcogenide materials made using the methods disclosed herein, and methods of use thereof.

### CROSS-REFERENCE TO RELATED APPLICATIONS

This application claims the benefit of priority to U.S. Provisional Application 63/113,752 filed Nov. 13, 2020, which is hereby incorporated herein by reference in its entirety.

### BACKGROUND

Transition metal dichalcogenides (TMDCs), with a direct band gap at single layer thicknesses, are widely studied in many fields, e.g., electrical, optical, electrochemical, biosensing, etc. Monolayers of transition metal dichalcogenides are desired for a variety of applications because of their atomic thickness, direct band gap, and other outstanding properties. Methods of making high-quality transition metal dichalcogenide monolayers with high-throughput are needed. The systems and methods discussed herein address these and other needs.

### SUMMARY

Disclosed herein are methods and systems for thinning a transition metal dichalcogenide material. For example, disclosed herein are methods of thinning a transition metal dichalcogenide material, the methods comprising: illuminating a first location of the transition metal dichalcogenide material with electromagnetic radiation while applying a positive potential between the transition metal dichalcogenide material and a gate electrode; wherein the transition metal dichalcogenide material has a thickness at the first location that is greater than a monolayer; wherein: when the thickness of the transition metal dichalcogenide material at a location is a monolayer, then the transition metal dichalcogenide material has a direct band gap; and when the thickness of the transition metal dichalcogenide material at the location is greater than a monolayer, then the transition metal dichalcogenide material has an indirect bandgap; wherein the indirect band gap has an energy that is the difference between a valence band and a conduction band; wherein the direct band gap has an energy that is the difference between a valence band and a conduction band; wherein the indirect band gap is lower in energy than the direct band gap; wherein the electromagnetic radiation has an energy that is less than the energy, of the direct band gap and greater than or equal to the energy of the indirect band gap; wherein the transition metal dichalcogenide material is disposed on a surface of a substrate; wherein a source electrode is disposed on the surface of the substrate; wherein the source electrode is in electrical contact with the transition metal dichalcogenide material; wherein the gate electrode is not in physical contact with the transition metal dichalcogenide material; wherein an aqueous solution is disposed on the surface of the substrate, such that the transition metal dichalcogenide material and the source electrode, are both submerged in the aqueous solution and the gate electrode is in electrochemical contact with the aqueous solution; and wherein the source electrode and gate electrode are connected to a power source configured to apply a positive potential between the source electrode and the gate electrode, thereby applying the positive potential between the transition metal dichalcogenide material and the gate electrode; thereby: promoting electrons from the valence band to the conduction band of the indirect band gap and decreasing the thickness of the transition metal dichalcogenide at the first location via electrochemical degradation, thereby thinning the transition metal dichalcogenide at the first location; wherein the method is self-limiting as the electrochemical degradation ceases when the thickness of the transition metal dichalcogenide at the first location is decreased to a monolayer, because the energy of the electromagnetic energy is insufficient to promote electrons from the valence band to the conduction band of the direct band gap.

In some examples, the transition metal dichalcogenide comprises MoS₂, WS₂, MoSe₂, WSe₂, MoTe₂, WTe₂, or a combination thereof. In some examples, the transition metal dichalcogenide comprises MoS₂.

In some examples, the electromagnetic radiation has a power density of from 0.1 mW/μm² to 30 mW/μm². In some examples, the power density of the electromagnetic radiation is 15 mW/μm² or less, 10 mW/μm² or less, or 5 mW/μm² or less,

In some examples, the electromagnetic radiation is provided by a light source and the light source is an artificial light source. In some examples, the artificial light source comprises a laser. In some examples, the transition metal dichalcogenide is MoS₂ and the electromagnetic radiation is provided by a 785 μm laser.

In some examples, the electromagnetic radiation is provided by an electromagnetic radiation source and the electromagnetic radiation source is configured to illuminate the first location.

In some examples, the electromagnetic radiation is provided by an electromagnetic radiation source and the electromagnetic radiation source is configured to illuminate a mirror and the mirror is configured to reflect the electromagnetic radiation from the electromagnetic radiation source to illuminate the first location. In some examples, the electromagnetic radiation is provided by an electromagnetic radiation source and the electromagnetic radiation source is configured to illuminate a plurality of mirrors and the plurality of mirrors are configured to reflect the electromagnetic radiation from the electromagnetic radiation source to illuminate the first location. In some examples, the electromagnetic radiation is provided by an electromagnetic radiation source and the electromagnetic radiation source is configured to illuminate a digital micromirror device comprising a plurality of mirrors and the plurality of mirrors are configured to reflect the electromagnetic radiation from the electromagnetic radiation source to illuminate the first location.

In some examples, the substrate is substantially transparent to the electromagnetic radiation. In some examples, the substrate is a dielectric substrate. In some examples, the substrate is glass.

In some examples, the positive potential is from greater than 0 V to 1 V. In some examples, the positive potential is from greater than 0 V to 0.5 V. In some examples, the positive potential is 0.5 V. In some examples, the transition metal dichalcogenide is MoS₂, the electromagnetic radiation is provided by a 785 μm laser, and the positive potential is 0.5 V.

In some examples, the gate electrode is disposed on the surface of the substrate such that the gate electrode is submerged in the aqueous solution.

In some examples, a drain electrode is further disposed on the surface of the substrate, wherein the drain electrode is in electrical contact with the transition metal dichalcogenide material and is submerged in the aqueous solution. In some examples, the source electrode, the gate electrode, and the drain electrode, when present, independently comprise a metal. In some examples, the source electrode, the gate electrode, and the drain electrode, when present, each comprise gold.

In some examples, the methods further comprise disposing the source electrode, on the surface of the substrate. In some examples, the methods further comprise disposing the gate electrode, the drain electrode, or a combination thereof on the surface of the substrate. In some examples, the source electrode, the drain electrode, the gate electrode, or a combination thereof are disposed on the surface of the substrate via photolithography.

In some examples, the aqueous solution is water.

In some examples, the first location is illuminated for an amount of time of from 1 second to 10 minutes. In some examples, the first location is illuminated for an amount of time of from 1 second to 150 seconds, from 1 second to 10 seconds, or from 100 seconds to 200 seconds.

In some examples, the methods further comprise illuminating a second location of the transition metal dichalcogenide material, wherein the transition metal dichalcogenide material has a thickness at the second location that is greater than a monolayer, thereby: promoting electrons from the valence band to the conduction band of the indirect band gap and decreasing the thickness of the transition metal dichalcogenide at the second location via electrochemical degradation, thereby thinning the transition metal dichalcogenide at the second location; wherein the method is self-limiting as the electrochemical degradation ceases when the thickness of the transition metal dichalcogenide at the second location is decreased to a monolayer, because the energy of the electromagnetic energy is insufficient to promote electrons from the valence band to the conduction band of the direct band gap.

In some examples, the substrate is translocated to illuminate the second location. In some examples, the electromagnetic radiation is provided by a light source, and the light source is translocated to illuminate the second location. In some examples, the electromagnetic radiation is provided by an electromagnetic radiation source, the electromagnetic radiation source being configured to illuminate a mirror and the mirror is configured to reflect the electromagnetic radiation from the electromagnetic radiation source to illuminate the transition metal dichalcogenide material, and the mirror is translocated to illuminate the second location.

In some examples, the second location is illuminated for an amount of time of from 1 second to 10 minutes. In some examples, the second location is illuminated for an amount of time of from 1 second to 150 seconds, from 1 second to 10 seconds, or from 100 seconds to 200 seconds.

In some examples, the method comprises: sequentially illuminating a plurality of locations by scanning the electromagnetic radiation across the transition metal dichalcogenide material; wherein the transition metal dichalcogenide material has a thickness at least a portion of the plurality of locations that is greater than a monolayer, said portion of the plurality of locations having a thickness that is greater than a monolayer being a first portion of the plurality of locations; thereby decreasing the thickness of the transition metal dichalcogenide at the first portion of the plurality of locations.

In some examples, the transition metal dichalcogenide material is scanned in a raster manner. In some examples, the substrate is translocated to sequentially illuminate the plurality of locations; wherein the electromagnetic radiation is provided by a light source, and the light source is translocated to sequentially illuminate the plurality of locations; wherein the electromagnetic radiation is provided by an electromagnetic radiation source, the electromagnetic radiation source being configured to illuminate a mirror and the mirror is configured to reflect the electromagnetic radiation from the electromagnetic radiation source to illuminate the transition metal dichalcogenide material, and the mirror is translocated to illuminate the plurality of locations; or a combination thereof.

In some examples, the electromagnetic radiation is scanned across the transition metal dichalcogenide material at a rate of from 0.1 micron per second to 10 microns per second. In some examples, the electromagnetic radiation is scanned across the transition metal dichalcogenide material at a rate of from 4 microns/second to 6 microns/second. In some examples, the electromagnetic radiation is scanned across the transition metal dichalcogenide material at a rate of 5 microns/second.

In some examples, the electromagnetic radiation is scanned across the transition metal dichalcogenide material for a total amount of time of from 1 second to 10 minutes. In some examples, the electromagnetic radiation is scanned across the transition metal dichalcogenide material for a total amount of time of from 1 second to 200 seconds, or from 100 seconds to 200 seconds.

In some examples, the transition metal dichalcogenide material has an area in the plane of the surface of the substrate of from 1 μm² to 7×10¹⁰ μm². In some examples, the transition metal dichalcogenide material has an area in the plane of the surface of the substrate of from 1000 μm² to 5000 μm², from 1000 μm² to 3000 μm², or from 2000 μm² to 3000 μm².

In some examples, the transition metal dichalcogenide material has an area in the plane of the surface of the substrate and the thickness of the transition metal dichalcogenide material is decreased to a monolayer over the entire area of the transition metal dichalcogenide material in the plan of the surface of the substrate.

In some examples, the methods further comprise removing the thinned transition metal dichalcogenide material from the substrate, thereby creating a free-standing thinned transition metal dichalcogenide material. In some examples, the methods further comprise depositing the free-standing thinned transition metal dichalcogenide material onto a second substrate.

Also disclosed herein are patterned transition metal dichalcogenide material made using any of the methods described herein.

Also disclosed herein are monolayers of transition metal dichalcogenides made using any of the methods described herein. In some examples, the monolayer has an area of from 1 μm² to 7×10¹⁰ μm². In some examples, the monolayer has an area of from 1000 μm² to 5000 μm², from 1000 μm² to 3000 μm², or from 2000 μm² to 3000 μm².

Also disclosed herein are methods of use of any of the patterned transition metal dichalcogenide materials and/or any of the monolayers of transition metal dichalcogenides described herein, the methods comprising using the transition metal dichalcogenide material and/or the monolayer of the transition metal dichalcogenide in an electronic device, a photonic device, or a combination thereof.

Also disclosed herein are methods of use of any of the patterned transition metal dichalcogenide materials and/or any of the monolayers of transition metal dichalcogenides described herein, the methods comprising using the transition metal dichalcogenide material and/or the monolayer of the transition metal dichalcogenide in photodetection, valleytronics, sensing, biomedical imaging, drug delivery, or a combination thereof.

Also disclosed herein are systems for thinning transition metal dichalcogenide materials, the systems comprising: a substrate having a surface; a transition metal dichalcogenide material, a source electrode, and aqueous solution disposed on the surface of the substrate; wherein the source electrode is in electrical contact with the transition metal dichalcogenide material; wherein the transition metal dichalcogenide material and the source electrode are both submerged in the aqueous solution; a gate electrode in electrochemical contact with the aqueous solution, wherein the gate electrode is not in physical contact with the transition metal dichalcogenide material; a power source connected to the source electrode and the gate electrode, wherein the power source is configured to apply a positive potential between the source electrode and the gate electrode, thereby applying a positive potential between the transition metal dichalcogenide material and the gate electrode; an electromagnetic radiation source configured to illuminate a first location of the transition metal dichalcogenide material with electromagnetic radiation; wherein the transition metal dichalcogenide material has a thickness at the first location that is greater than a monolayer; wherein: when the thickness of the transition metal dichalcogenide material at a location is a monolayer, then the transition metal dichalcogenide material has a direct band gap; and when the thickness of the transition metal dichalcogenide material at the location is greater than a monolayer, then the transition metal dichalcogenide material has an indirect bandgap; wherein the indirect band gap has an energy that is the difference between a valence band and a conduction band; wherein the direct band gap has an energy that is the difference between a valence band and a conduction band; wherein the indirect band gap is lower in energy than the direct band gap; and wherein the electromagnetic radiation has an energy that is less than the energy of the direct band gap and greater than or equal to the energy of the indirect band gap; such that when the first location of the transition metal dichalcogenide material is illuminated with the electromagnetic radiation from the electromagnetic radiation source while the power source applies the positive potential between the transition metal dichalcogenide material and the gate electrode, then: electrons are promoted from the valence band to the conduction band of the indirect band gap and the thickness of the transition metal dichalcogenide at the first location is decreased via electrochemical degradation, thereby thinning the transition metal dichalcogenide at the first location; wherein the thinning is self-limiting as the electrochemical degradation ceases when the thickness of the transition metal dichalcogenide at the first location is decreased to a monolayer, because the energy of the electromagnetic energy is insufficient to promote electrons from the valence band to the conduction band of the direct band gap. In some examples, the gate electrode is disposed on the surface of the substrate such that the gate electrode is submerged in the aqueous solution. In some examples, the electromagnetic radiation source comprises a light source and the light source comprises an artificial light source. In some examples, the artificial light source comprises a laser. In some examples, the system further comprises a means for translocating the substrate and/or the electromagnetic radiation source. In some examples, the aqueous solution is water. In some examples, the first location is illuminated for an amount of time of from 1 second to 10 minutes. In some examples, the first location is illuminated for an amount of time of from 1 second to 150 seconds, from 1 second to 10 seconds, or from 100 seconds to 200 seconds. In some examples, the transition metal dichalcogenide comprises MoS₂, WS₂, MoSe₂, WSe₂, MoTe₂, MTe₂, or a combination thereof. In some examples, the transition metal dichalcogenide comprises MoS₂. In some examples, the electromagnetic radiation has a power density of from 0.1 mW/μm² to 30 mW/μm². In some examples, the power density of the electromagnetic radiation is 15 mW/μm² or less, 10 mW/μm² or less, or 5 mW/μm² or less. In some examples, the transition metal dichalcogenide is MoS₂ and the electromagnetic radiation source is a 785 nm laser. In some examples, the substrate is substantially transparent to the electromagnetic radiation. In some examples, the substrate is a dielectric substrate. In some examples, the substrate is glass. In some examples, the positive potential is from greater than 0 V to 1 V. In some examples, the positive potential is from greater than 0 V to 0.5 V. In some examples, the positive potential is 0.5 V. In some examples, the transition metal dichalcogenide is MoS2, the electromagnetic radiation source is a 785 nm laser, and the positive potential is 0.5 V. In some examples, the transition metal dichalcogenide material has an area in the plane of the surface of the substrate of from 1 μm² to 7×10¹⁰ μm². In some examples, the transition metal dichalcogenide material has an area in the plane of the surface of the substrate of from 1000 μm² to 5000 μm², from 1000 μm² to 3000 μm², or from 2000 μm² to 3000 μm². In some examples, the transition metal dichalcogenide material has an area in the plane of the surface of the substrate and the thickness of the transition metal dichalcogenide material is decreased to a monolayer over the entire area of the transition metal dichalcogenide material in the plane of the surface of the substrate.

In some examples, the systems further comprise a lens. In some examples, the system is configured such that the electromagnetic radiation from the electromagnetic radiation source traverses the lens and the substrate to illuminate the first location of the transition metal dichalcogenide material. In some examples, the lens comprises a microscope objective.

In some examples, the system further comprises an inverted microscope having a stage, and the substrate is mounted on the stage of the inverted microscope.

In some examples, the system further comprises an instrument configured to capture an electromagnetic signal from the transition metal dichalcogenide material. In some examples, the system further comprises a computing device comprising a processor and a memory operably coupled to the processor, the memory having further computer-executable instructions stored thereon that, when executed by the processor, cause the processor to: receive an electromagnetic signal from the instrument; process the electromagnetic signal to obtain a characteristic of the transition metal dichalcogenide material; and output the characteristic of the transition metal dichalcogenide material.

In some examples, the instrument comprises a camera, an optical microscope, an electron microscope, a spectrometer, or combinations thereof. In some examples, the instrument comprises a spectrometer and the spectrometer comprises a Raman spectrometer, a UV-vis absorption spectrometer, an IR absorption spectrometer, a fluorescence spectrometer, a photoluminescence spectrometer, or combinations thereof.

In some examples, the system further comprises a drain electrode disposed on the surface of the substrate, wherein the drain electrode is in electrical contact with the transition metal dichalcogenide material and is submerged in the aqueous solution. In some examples, the source electrode, the gate electrode, and the drain electrode, when present, independently comprise a metal. In some examples, the source electrode, the gate electrode, and the drain electrode, when present, each comprise gold.

In some examples, the system further comprises a mirror. In some examples, the system is aligned such that the electromagnetic radiation source is configured to illuminate the mirror and the mirror is configured to reflect the electromagnetic radiation from the electromagnetic radiation source to illuminate the first location. In some examples, the mirror is a plurality of mirrors. In some examples, the mirror is a digital micromirror device comprising a plurality of mirrors. In some examples, the system further comprises a means for translocating the mirror.

In some examples, the system further comprises a computing device comprising a processor and a memory operably coupled to the processor, the memory having further computer-executable instructions stored thereon that, when executed by the processor, cause the processor to send a control signal to the means for translocating the substrate, the means for translocating the electromagnetic radiation source, the means for translocating the mirror, or a combination thereof, thereby: translocating the substrate, the electromagnetic radiation source, the mirror, or a combination thereof, such that the electromagnetic radiation source is configured to illuminate the transition metal dichalcogenide material at a second location while the power source is configured to apply the positive potential between the transition metal dichalcogenide material and the gate electrode, wherein the transition metal dichalcogenide material has a thickness at the second location that is greater than a monolayer; such that when the second location of the transition metal dichalcogenide material is illuminated with the electromagnetic radiation from the electromagnetic radiation source while the power source applies the positive potential between the transition metal dichalcogenide material and the gate electrode, then: electrons are promoted from the valence band to the conduction band of the indirect band gap and the thickness of the transition metal dichalcogenide at the second location is decreased via electrochemical degradation, thereby thinning the transition metal dichalcogenide at the second location; wherein the thinning is self-limiting as the electrochemical degradation ceases when the thickness of the transition metal dichalcogenide at the second location is decreased to a monolayer, because the energy of the electromagnetic energy is insufficient to promote electrons from the valence band to the conduction band of the direct band gap. In some examples, the second location is illuminated for an amount of time of from 1 second to 10 minutes. In some examples, the second location is illuminated for an amount of time of from 1 second to 150 seconds, from 1 second to 10 seconds, or from 100 seconds to 200 seconds.

In some examples, the system further comprises a computing device comprising a processor and a memory operably coupled to the processor, the memory having further computer-executable instructions stored thereon that, when executed by the processor, cause the processor to send a control signal to the means for translocating the substrate, the means for translocating the electromagnetic radiation source, the means for translocating the mirror, or a combination thereof, thereby: translocating the substrate, the electromagnetic radiation source, the mirror, or a combination thereof, such that the electromagnetic radiation source is configured to sequentially illuminate the transition metal dichalcogenide material at a plurality of locations by scanning the electromagnetic radiation across the transition metal dichalcogenide material while the power source is configured to apply the positive potential between the transition metal dichalcogenide material and the gate electrode, wherein the transition metal dichalcogenide material has a thickness at least a portion of the plurality of locations that is greater than a monolayer, said portion of the plurality of locations having a thickness that is greater than a monolayer being a first portion of the plurality of locations; thereby decreasing the thickness of the transition metal dichalcogenide at the first portion of the plurality of locations. In some examples, the transition metal dichalcogenide material is scanned in a raster manner. In some examples, the electromagnetic radiation is scanned across the transition metal dichalcogenide material at a rate of from 0.1 micron per second to 10 microns per second. In some examples, the electromagnetic radiation is scanned across the transition metal dichalcogenide material at a rate of from 4 microns/second to 6 microns/second. In some examples, the electromagnetic radiation is scanned across the transition metal dichalcogenide material at a rate of 5 microns/second. In some examples, the electromagnetic radiation is scanned across the transition metal dichalcogenide material for a total amount of time of from 1 second to 10 minutes. In some examples, the electromagnetic radiation is scanned across the transition metal dichalcogenide material for a total amount of time of from 1 second to 200 seconds, or from 100 seconds to 200 seconds.

Additional advantages of the invention will be set forth in part in the description which follows, and in part will be obvious from the description, or may be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1 is a schematic (cross-section) of an example system as disclosed herein for thinning a transition metal dichalcogenide material.

FIG. 2 is a schematic of an example system as disclosed herein for thinning a transition metal dichalcogenide material.

FIG. 3 is a schematic of an example system as disclosed herein for thinning a transition metal dichalcogenide material.

FIG. 4 is a schematic of an example system as disclosed herein for thinning a transition metal dichalcogenide material.

FIG. 5 is a schematic of an example system as disclosed herein for thinning a transition metal dichalcogenide material.

FIG. 6 is a schematic of an example system as disclosed herein for thinning a transition metal dichalcogenide material.

FIG. 7 is a schematic of an example system as disclosed herein for thinning a transition metal dichalcogenide material.

FIG. 8 is a schematic of an example computing device.

FIG. 9 is a schematic illustration of the sample (cross-sectional view) and experimental set up for the self-limiting optoelectronic thinning.

FIG. 10 is an optical micrograph of MoS₂ before thinning. Scale bar is 20 μm.

FIG. 11 is an optical micrograph of the MoS₂ shown in FIG. 10 after thinning. Scale bar is 20 μm.

FIG. 12 is the photoluminescence spectra of exfoliated MoS₂ monolayer (blue; middle trace), and of a MoS₂ flake before (yellow; bottom trace) and after (red; top trace) thinning, measured at the positions indicated by the square in FIG. 10 and the square in FIG. 11, respectively.

FIG. 13 is the Raman spectra of exfoliated MoS₂ monolayer (blue: bottom trace), and of a MoS₂ flake before (yellow; top trace) and after (red; middle trace) thinning, measured at the positions indicated by the square in FIG. 10 and the square in in FIG. 11, respectively. Scale bars are 20 μm.

FIG. 14 is a MoS₂ flake at 0.5 V potential. Scale bar is 25 μm.

FIG. 15 is the MoS₂ flake shown in FIG. 14 after 15 mins in darkness. Scale bar is 25 μm.

FIG. 16 is the MoS₂ flake shown in FIG. 14 and FIG. 15 after being illuminated by 785 nm laser for 4 seconds. Scale bar is 25 μm.

FIG. 17 is a MoS₂ flake connected to a gold electrode in DI water before being illuminated by a 785 nm laser. Scale bar is 10 μm.

FIG. 18 is the MoS₂ flake shown in FIG. 17 connected to a gold electrode in Di water after being illuminated by a 785 nm laser. Scale bar is 10 μm.

FIG. 19 is the photoluminescence spectra of bilayer MoS₂ at different potentials from −0.5 V (bottom trace) to 0.5 V (top trace).

FIG. 20 is the photoluminescence spectra of an isolated monolayer flake (orange; lower trace) and a monolayer flake connected to a gold electrode (blue; upper trace).

FIG. 21 is a schematic illustration of the thinning process.

FIG. 22 is a schematic illustration of the distribution of electrons and holes under different vertical electric fields.

FIG. 23 is an optical micrograph of a MoS₂ flake before being thinned by a 532 nm laser beam. Scale bar is 5 μm.

FIG. 24 is an optical micrograph of the MoS₂ flake from FIG. 23 after being thinned by a 532 nm laser beam. Scale bar is are 5 μm.

FIG. 25 is an optical micrograph of a MoS₂ flake before being thinned by a 785 nm laser beam. Scale bar is 10 μm.

FIG. 26 is an optical micrograph of the MoS₂ flake shown in FIG. 25 after being thinned by a 785 nm laser beam. Scale bar is 10 μm.

FIG. 27 is the photoluminescence spectra measured from flakes scanned by a 532 nm laser beam (blue; lower trace) and a 785 nm laser beam (orange; upper trace) as indicated by the square in FIG. 24 and the square in FIG. 26, respectively.

FIG. 28. General concept of sOET. A self-limiting opto-electrochemical thinning (SOFT) technique is developed for the on-demand fabrication of high-quality transition metal dichalcogenide (TMD) thin films. Precise thickness control can be achieved by tuning the incident light wavelengths according to the thickness-dependent bandgap structure of transition metal dichalcogenide materials. For example, a 785 am laser leads to the thinning of a thick MoS₂ flake to monolayers, while a 532 nm laser removes all the flake.

FIG. 29. Schematic showing the experimental setup of sOET.

FIG. 30. Optical image of a thick MoS₂ flake on ITO before thinning. The same flake after being partially thinned by a 785 nm laser is shown in FIG. 31. The laser scanned area is indicated by the white dashed square. Scale bar is 20 μm.

FIG. 31. The same flake shown in FIG. 30 after partially thinned by a 785 nm laser. The laser scanned area is indicated by the white dashed square. Scale bar is 20 μm.

FIG. 32. Photoluminescence (PL) spectra of the flake before (blue) and after (red) thinning. The inset shows the Raman scattering spectra before (blue, top trace) and after (red, bottom trace) thinning.

FIG. 33. AFM image of the thinned flake. Scale bar is 20 μm.

FIG. 34. AFM height profile of the red line in FIG. 33 from top-right to bottom-left.

FIG. 35. Spatial mapping of the Raman frequency distance between E¹_{2g} mode and A_{1g} mode of the of the thinned MoS₂ in FIG. 31. The reduced Raman frequency distance of 20.5 cm⁻¹ indicates the monolayer feature in the laser scanned area.

FIG. 36. Spatial mapping of the integrated photoluminescence intensity from 600 nm to 750 nm of the of the thinned MoS₂ in FIG. 31. The enhanced photoluminescence intensity indicates the monolayer feature in the laser scanned area.

FIG. 37. Photoluminescence (PL) spectra of the thinned MoS₂ before and after laser excitation of 30 min. No obvious difference in the photoluminescence intensity was observed.

FIG. 38. Optical image of a thick MoS₂ flake in ethanol before laser scanning. The same flake after laser scanning in ethanol is shown in FIG. 39.

FIG. 39. Optical image of the same MoS₂ flake shown in FIG. 38 after laser scanning in ethanol. The gate current during laser scanning in ethanol is shown in FIG. 40.

FIG. 40. Gate current during the laser scanning of the MoS₂ flake in ethanol.

FIG. 41. Optical image of a thick MoS₂ flake in BMIM-PF6 before laser scanning. The same flake after laser scanning in BMIM-PF6 is shown in FIG. 42.

FIG. 42. Optical image of the same MoS₂ flake shown in FIG. 41 after laser scanning in BMIM-PF6. The gate current during laser scanning in BMIM-PF6 is shown in FIG. 43.

FIG. 43. Gate current during the laser scanning of the MoS₂ flake in BMIM-PF6.

FIG. 44. Optical image of a thick MoS₂ flake in DI water before laser scanning. The same flake after laser scanning in DI water is shown in FIG. 45.

FIG. 45. Optical image of the same MoS₂ flake shown in FIG. 44 after laser scanning in DI water. The gate current during laser scanning in DI water is shown in FIG. 46.

FIG. 46. Gate current during laser scanning of the MoS₂ flake in DI water.

FIG. 47. Optical image of a MoS₂ flake. Scale bar: 10 μm.

FIG. 48. Background temperature distribution when the laser was off, the ambient temperature was ˜22° C.

FIG. 49. Temperature distribution when a a 0.102 mW μm² 785 nm laser was directed on the MoS₂ flake in DI water.

FIG. 50. Cross-sections of the temperature distribution with the laser off/on made at the white dashed line in FIG. 48 and FIG. 49.

FIG. 51. Optical image of a MoS₂ flake on 5 nm gold film. The same flake after being illuminated by a 0.256 mW μm⁻² 785 nm laser for 30 s in DI water with no bias is shown in

FIG. 52. Scale bar is 25 μm.

FIG. 52. Optical image of the MoS₂ flake on 5 nm gold film shown in FIG. 51 after being illuminated by a 0.256 mW μm² 785 nm laser for 30 s in DI water with no bias. Even without applying bias, the thickness of the multilayer MoS₂ was reduced. Scale bar is 25 μm.

FIG. 53. Optical image of a MoS₂ flake on monolayer graphene (glass substrate). The same flake after being illuminated by a 0.257 mW μm² 785 nm laser for 30 s DI water without bias is shown in FIG. 52. Scale bar is 25 μm.

FIG. 54. Optical image of the MoS₂ flake on monolayer graphene (glass substrate) shown in FIG. 53 after being illuminated by a 0.257 mW μm⁻² 785 nm laser for 30 s DI water without bias. Even without applying bias, the thickness of the multilayer MoS₂ was reduced. Scale bar is 25 μm.

FIG. 55. Photoluminescence (PL) spectra before (blue dashed) and after thinning.

FIG. 56. Thinning rate of sOET tuned by laser power.

FIG. 57. Thinning rate of sOET tuned by bias voltage.

FIG. 58. Thinning rate of sOET tuned by pH value.

FIG. 59. Thinning rate of sOET tuned by NaCl concentration.

FIG. 60. Working principle of thickness-selective thinning of MoS₂ via sOET. By choosing excitation laser wavelength between these discrete layer-dependent bandgaps, the thinning will stop once the bandgap of the remaining layers is larger than the laser photon energy.

FIG. 61. A thick MoS₂ flake before thinning. The same flake after thinning is shown in

FIG. 62. Scale bar is 10 μm.

FIG. 62. The same MoS₂ flake in FIG. 61 after being thinned by 532 nm, 785 nm, 850 nm, and 980 nm lasers, from top to bottom. The scanned paths are indicated by the green (532 nm), red (785 nm), grey (850 nm), and black (980 nm) lines. Scale bar is 10 μm,

FIG. 63. Photoluminescence (PL) spectra measured at the laser-scanned areas.

FIG. 64. Photoluminescence mapping of the thinned regions (indicated by the white dashed rectangle in FIG. 62).

FIG. 65. Raman mapping of the thinned regions (indicated by the white dashed rectangle in FIG. 62).

FIG. 66. Raman spectra of MoS₂ flakes after scanning by different lasers.

FIG. 67. Optical image of a large thick MoS₂ flake. The same flake after thinning is shown in FIG. 68. Scale bar is 25 μm.

FIG. 68. Optical image of the flake in FIG. 67 after being thinned by a 785 nm laser. Scale bar is 25 μm.

FIG. 69. Fluorescence image of the thinned flake in FIG. 68. Scale bar is 25 μm.

FIG. 70. Normalized photoluminescence (PL) spectra of the mechanically exfoliated and sOET thinned monolayer MoS₂, which are comparable.

FIG. 71. Raman scattering spectra of the mechanically exfoliated and sOET thinned monolayer MoS₂, which are comparable.

FIG. 72. Optical image of a WSe₂ flake before thinning. An optical image of the WSe₂ flake after thinning is shown in FIG. 73. Scale bar is 10 μm.

FIG. 73. Optical image of the WSe₂ flake shown in FIG. 72 after thinning. Scale bar is 10 μm.

FIG. 74. Photoluminescence (PL) spectra of the WeS₂ flake before and after thinning.

### DETAILED DESCRIPTION

The systems and methods described herein may be understood more readily by reference to the following detailed description of specific aspects of the disclosed subject matter and the Examples included therein.

Before the present systems and methods are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises.” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

Disclosed herein are methods of thinning a transition metal dichalcogenide material. As used herein, a “transition metal dichalcogenide” refers to a compound comprising a transition metal and two chalcogen atoms. As used herein, a “transition metal” refers to any element from groups 3-12, such as Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, Hg, and Ac. As used herein a “chalcogen” refers to any element from group 16, such as oxygen, sulfur, selenium, tellurium, and polonium. As such, transition metal chalcogenides can include transition metal oxides, transition metal sulfides, and transition metal selenides, among others. For example, the transition metal dichalcogenide can comprise MoS₂, WS₂, MoSe₂, WSe₂, MoTe₂, WTe₂, or a combination thereof. In some examples, the transition metal dichalcogenide comprises MoS₂.

The transition metal dichalcogenide material is disposed on a surface of a substrate. In some examples, the transition dichalcogenide material is disposed on the surface of the substrate such that the transition metal dichalcogenide material is in physical contact with the surface of the substrate. The substrate can comprise any suitable substrate. In some examples, the substrate can be substantially transparent, In some examples, the substrate is non-transparent. In some examples, the substrate can comprise a dielectric material. In some examples, the substrate can comprise glass, quartz, silicon dioxide, a polymer, or a combination thereof. In some examples, the substrate is glass. In some examples, the substrate can be conductive. In some examples, the substrate can comprise ITO coated glass. In some examples, the substrate can comprise silicon.

In some examples, the methods can comprise forming the transition metal dichalcogenide material. In some examples, the methods can further comprise disposing the transition metal dichalcogenide material on the surface of the substrate.

The transition metal dichalcogenide material has an area in the plane of the surface of the substrate. For example, the transition metal dichalcogenide material can have an area in the plane of the surface of the substrate of 1 micrometer squared (μm²) or more (e.g., 5 μm² or more, 10 μm² or more, 15 μm² or more, 20 μm² or more, 25 μm² or more, 30 μm² or more, 35 μm² or more, 40 μm² or more, 45 μm² or more, 50 μm² or more, 60 μm² or more, 70 μm² or more, 80 μm² or more, 90 μm² or more, 100 μm² or more, 125 μm² or more, 150 μm² or more, 175 μm² or more, 200 μm² or more, 225 μm² or more, 250 μm² or more, 300 μm² or more, 350 μm² or more, 400 μm² or more, 450 μm² or more, 500 μm² or more, 600 μm² or more, 700 μm² or more, 800 μm² or more, 900 μm² or more, 1000 μm² or more, 1250 μm² or more, 1500 μm² or more, 1750 μm² or more, 2000 μm² or more, 2250 μm² or more, 2500 μm² or more, 2750 μm² or more, 3000 μm² or more, 3500 μm² or more, 4000 μm² or more, 4500 μm² or more, 5000 μm² or more, 6000 μm² or more, 7000 μm² or more, 8000 μm² or more, 9000 μm² or more, 1×10⁴ μm² or more, 2×10⁴ μm² or more, 3×10⁴ μm² or more, 4×10⁴ μm² or more, 5×10⁴ μm² or more, 6×10⁴ μm² or more, 7×10⁴ μm² or more, 8×10⁴ μm² or more, 9×10⁴ μm² or more, 1×10⁵ μm² or more, 2,5×10⁵ μm² or more, 5×10⁵ μm² or more, 7.5×10⁵ μm² or more, 1×10⁶ μm² or more, 2.5×10⁶ μm² or more, 5×10⁶ μm² or more, 7.5×10⁶ μm² or more, 1×10⁷ μm² or more, 2.5×10⁷ μm² or more, 5×10⁷ μm² or more, 7.5×10⁷ μm² or more, 1×10⁸ μm² or more, 2.5×10⁸ μm² or more, 5×10⁸ μm² or more, 7.5×10⁸ μm² or more, 1×10⁹ μm² or more, 2.5×10⁹ μm² or more, 5×10⁹ μm² or more, 7.5×10⁹ μm² or more, 1×10¹⁰ μm² or more, 2.5×10¹⁰ μm² or more, or 5×10¹⁰ μm² or more).

In some examples, the transition metal dichalcogenide material can have an area in the plane of the surface of the substrate of 7×10¹⁰ μm² or less (e.g., 5×10¹⁰ μm² or less, 2.5×10¹⁰ μm² or less, 1×10¹⁰ μm² or less, 7.5×10⁹ μm² or less, 5×10⁹ μm² or less, 2.5×10⁹ μm² or less, 1×10⁹ μm² or less, 7.5×10⁸ μm² or less, 5×10⁸ μm² or less, 2.5×10⁸ μm² or less, 1×10⁸ μm² or less, 7.5×10⁷ μm² or less, 5×10⁷ μm² or less, 2.5×10⁷ μm² or less, 1×10⁷ μm² or less, 7.5×10⁶ μm² or less, 5×10⁶ μm² or less, 2.5×10⁶ μm² or less, 1×10⁶ μm² or less, 7.5×10⁵ μm² or less, 5×10⁵ μm² or less, 2.5×10⁵ μm² or less, 1×10⁵ μm² or less, 9×10⁴ μm² or less, 8×10⁴ μm² or less, 7×10⁴ μm² or less, 6×10⁴ μm² or less, 5×10⁴ μm² or less, 4×10⁴ μm² or less, 3×10⁴ μm² or less, 2×10⁴ μm² or less, 1×10⁴ μm² or less, 9000 μm² or less, 8000 μm² or less, 7000 μm² or less, 6000 μm² or less, 5000 μm² or less, 4500 μm² or less, 4000 μm² or less, 3500 μm² or less, 3000 μm² or less, 2750 μm² or less, 2500 μm² or less, 2250 μm² or less, 2000 μm² or less, 1750 μm² or less, 1500 μm² or less, 1250 μm² or less, 1000 μm² or less, 900 μm² or less, 800 μm² or less, 700 μm² or less, 600 μm² or less, 500 μm² or less, 450 μm² or less, 400 μm² or less, 350 μm² or less, 300 μm² or less, 250 μm² or less, 225 μm² or less, 200 μm² or less, 175 μm² or less, 150 μm² or less, 125 μm² or less, 100 μm² or less, 90 μm² or less, 80 μm² or less, 70 μm² or less, 60 μm² or less, 50 μm² or less, 45 μm² or less, 40 μm² or less, 35 μm² or less, 30 μm² or less, 25 μm² or less, 20 μm² or less, 15 μm² or less, or 10 μm² or less).

The area of the transition metal dichalcogenide material in the plane of the surface of the substrate can range from any of the minimum values described above to any of the maximum values described above. For example, the transition metal dichalcogenide material can have an area in the plane of the surface of the substrate of from 1 μm² to 7×10¹⁰ μm² (e.g., from 1 μm² to 1000 μm², from 1000 to 1×10⁶ μm², from 1×10⁶ μm² to 7×10¹⁰ μm², from 1 μm² to 1×10⁹ μm², from 1 μm² to 1×10⁷ μm², from 1 μm² to 1×10⁵ μm², from 1 μm² to 5000 μm², from 1000 μm² to 5000 μm², from 1000 μm² to 3000 μm², or from 2000 μm² to 3000 μm²).

The transition metal dichalcogenide material has a thickness (e.g., dimension perpendicular to the surface of the substrate). When the thickness of the transition metal dichalcogenide material at a location is a monolayer (e.g., a single atomic layer), then the transition metal dichalcogenide material has a direct band gap; and when the thickness of the transition metal dichalcogenide material at the location is greater than a monolayer, then the transition metal dichalcogenide material has an indirect bandgap; wherein the indirect band gap has an energy that is the difference between a valence band and a conduction band; wherein the direct band gap has an energy that is the difference between a valence band and a conduction band; and wherein the indirect band gap is lower in energy than the direct band gap.

A source electrode is also disposed on the surface of the substrate, wherein the source electrode is in electrical contact with the transition metal dichalcogenide material. In some examples, the source electrode is in physical contact with the transition metal dichalcogenide material. In some examples, the source electrode is in physical and electrical contact with the transition metal dichalcogenide material.

An aqueous solution is also disposed on the surface of the substrate, such that the transition metal dichalcogenide material, and the source electrode are both submerged in the aqueous solution. The aqueous solution can, for example, comprise water (e.g., deionized water). In some examples, the aqueous solution consists essentially of water. In some examples, the aqueous solution consists of water.

A gate electrode is in electrochemical contact with the aqueous solution. The gate electrode is not in physical contact with the transition metal dichalcogenide material. In some examples, the gate electrode is disposed on the surface of the substrate such that the gate electrode is submerged in the aqueous solution.

The source electrode and gate electrode are connected to a power source configured to apply a positive potential between the source electrode and the gate electrode, thereby applying a positive potential between the transition metal dichalcogenide material and the gate electrode.

In some examples, a drain electrode is also disposed on the surface of the substrate, wherein the drain electrode is in electrical contact with the transition metal dichalcogenide material and is submerged in the aqueous solution. In some examples, In some examples, the drain electrode is in physical contact with the transition metal dichalcogenide material. In some examples, the drain electrode is in physical and electrical contact with the transition metal dichalcogenide material.

Examples of suitable electrode materials are known in the art. The source electrode, the drain electrode (when present), and the gate electrode can each independently comprise, for example, a transparent conducting oxide, a metal oxide, a conducting polymer, a carbon material, a metal, or a combination thereof. In some examples, the source electrode, the drain electrode (when present), and the gate electrode independently comprise a metal. In some examples, the source electrode, the drain electrode (when present), and the gate electrode each comprise gold.

In some examples, the methods can comprise disposing the source electrode on the surface of the substrate. In some examples, the methods can further comprise disposing the drain electrode, the gate electrode, or a combination thereof on the surface of the substrate. Depositing the source electrode, the drain electrode, the gate electrode, or a combination thereof on the surface of the substrate can comprise, for example, printing, lithographic deposition, electron beam deposition, thermal deposition, or combinations thereof. For example, the source electrode, the drain electrode, the gate electrode, or a combination thereof can be disposed on the surface of the substrate via photolithography.

The methods of thinning a transition metal dichalcogenide material comprise illuminating a first location of the transition metal dichalcogenide material with electromagnetic radiation while applying a positive potential between the transition metal dichalcogenide material and a gate electrode; wherein the transition metal dichalcogenide material has a thickness at the first location that is greater than a monolayer; wherein the electromagnetic radiation has an energy that is less than the energy of the direct band gap and greater than or equal to the energy of the indirect band gap; thereby: promoting electrons from the valence band to the conduction band of the indirect band gap and decreasing the thickness of the transition metal dichalcogenide at the first location via electrochemical degradation, thereby thinning the transition metal dichalcogenide at the first location; wherein the method is self-limiting as the electrochemical degradation ceases when the thickness of the transition metal dichalcogenide at the first location is decreased to a monolayer, because the energy of the electromagnetic energy is insufficient to promote electrons from the valence band to the conduction band of the direct band gap. In some examples, the substrate is substantially transparent to the electromagnetic radiation.

As used herein, “a first location” and “the first location” are meant to include any number of locations in any arrangement. Thus, for example “a first location” includes one or more first locations. In some embodiments, the first location can comprise a plurality of locations. In some embodiments, the first locations can comprise a plurality of locations arranged in an ordered array.

The electromagnetic radiation can, for example, have a power density of 0.1 mW/μm² or more (e.g., 0.2 mW/μm² or more, 0.3 mW/μm² or more, 0.4 mW/μm² or more, 0.5 mW/μm² or more, 1 mW/μm² or more, 1.5 mW/μm² or more, 2 mW/μm² or more, 2.5 mW/μm² or more, 3 mW/μm² or more, 3.5 mW/μm² or more, 4 mW/μm² or more, 4.5 mW/μm² or more, 5 mW/μm² or more, 6 mW/μm² or more, 7 mW/μm² or more, 8 mW/μm² or more, 9 mW/μm² or more, 10 mW/μm² or more, 15 mW/μm² or more, 20 mW/μm² or more, or 25 mW/μm² or more). In some examples, the electromagnetic radiation can have a power density of 30 mW/μm² or less (e.g., 25 mW/μm² or less, 20 mW/μm² or less, 15 mW/μm² or less, 10 mW/μm² or less, 9 mW/μm² or less, 8 mW/μm² or less, 7 mW/μm² or less, 6 mW/μm² or less, 5 mW/μm² or less, 4.5 mW/μm² or less, 4 mW/μm² or less, 3.5 mW/μm² or less, 3 mW/μm² or less, 2.5 mW/μm² or less, 2 mW/μm² or less, 1.5 mW/μm² or less, 1 mW/μm² or less, 0.5 mW/μm² or less, 0.4 mW/μm² or less, 0.3 mW/μm² or less, or 0.2 mW/μm² or less). The power density of the electromagnetic radiation can range from any of the minimum values described above to any of the maximum values described above. For example, the electromagnetic radiation can have a power density of from 0.1 mW/μm² to 30 mW/μm² (e.g., from 0.1 mW/μm² to 15 mW/μm², from 15 mW/μm² to 30 mW/μm², from 0.1 mW/μm² to 10 mW/μm², from 10 mW/μm² to 20 mW/μm², from 20 mW/μm² to 30 mW/μm², from 0.1 mW/μm² to 20 mW/μm², or from 0.1 mW/μm² to 5 mW/μm²).

The electromagnetic radiation can, for example, be provided by an electromagnetic radiation source. In some examples, the electromagnetic radiation can be provided by a light source. The light source can be any type of light source. Examples of suitable light sources include natural light sources (e.g., sunlight) and artificial light sources (e.g., incandescent light bulbs, light emitting diodes, gas discharge lamps, arc lamps, lasers etc.). In some examples, the light source is a laser. In some examples, the transition metal dichalcogenide is MoS₂ and the electromagnetic radiation is provided by a 785 nm laser.

In some examples, the electromagnetic radiation source is configured to illuminate a minor, the mirror being configured to reflect the electromagnetic radiation from the electromagnetic radiation source to illuminate the first location. In some examples, the mirror can comprise a plurality of mirrors, such as an array of micromirrors (e.g., a digital micromirror device).

The positive potential can, for example, be greater than 0 Volts (V) (e.g., 0.1 V or more, 0.2 V or more, 0.3 V or more, 0.4 V or more, 0.5 V or more, 0.6 V or more, 0.7 V or more, 0.8 V or more, or 0.9 V or more). In some examples, the positive potential can be 1 V or less (e.g., 0.9 V or less, 0.8 V or less, 0.7 V or less, 0.6 V or less, 0.5 V or less, 0.4 V or less, 0.3 V or less, 0.2 V or less, or 0.1 V or less). The positive potential can range from any of the minimum values described above to any of the maximum values described above. For example, the positive potential can be from greater than 0 V to 1 V (e.g., from greater than 0 V to 0.5 V, from 0.5 V to 1 V, from greater than 0 V to 0.3 V, from 0.3 V to 0.6 V, from 0.6 V to 1 V, from greater than 0 V to 0.9 V, from 0.1 V to 1 V, from 0.1 V to 0.9 V, from 0.2 V to 0.8 V, or from 0.4 V to 0.6 V). In some examples, the positive potential is 0.5 V. In some examples, the transition metal dichalcogenide is MoS₂, the electromagnetic radiation is provided by a 785 nm laser, and the positive potential is 0.5 V.

The first location can, for example, be illuminated for an amount of time of 1 second or more (e.g., 2 seconds or more, 3 seconds or more, 4 seconds or more, 5 seconds or more, 10 seconds or more, 15 seconds or more, 20 seconds or more, 25 seconds or more, 30 seconds or more, 35 seconds or more, 40 seconds or more, 45 seconds or more, 50 seconds or more, 55 seconds or more, 1 minute or more, 1,5 minutes or more, 2 minutes or more, 2.5 minutes or more, 3 minutes or more, 3.5 minutes or more, 4 minutes or more, 4.5 minutes or more, 5minutes or more, 6 minutes or more, 7 minutes or more, 8 minutes or more, or 9 minutes or more). In some examples, the first location can be illuminated for an amount of time of 10 minutes or less (e.g., 9 minutes or less, 8 minutes or less, 7 minutes or less, 6 minutes or less, 5 minutes or less, 4.5 minutes or less, 4 minutes or less, 3.5 minutes or less, 3 minutes or less, 2.5 5 minutes or less, 2 minutes or less, 1.5 minutes or less, 1 minute or less, 55 seconds or less, 50 seconds or less, 45 seconds or less, 40 seconds or less, 35 seconds or less, 30 seconds or less, 25 seconds or less, 20 seconds or less, 15 seconds or less, 10 seconds or less, 5 seconds or less, 4 seconds or less, 3 seconds or less, or 2 seconds or less). The amount of time the first location is illuminated can range from any of the minimum values described above to any of the maximum 10 values described above. For example, the first location can be illuminated for an amount of time of from 1 second to 10 minutes (e.g., from 1 second to 1 minute, from 1 minute to 10 minutes, from 1 second to 5 minutes, from 5 minutes to 10 minutes, from 1 second to 150 seconds, from 1 second to 10 seconds, or from 100 seconds to 200 seconds).

The power density of the electromagnetic radiation, the positive potential applied, the amount of time the first location is illuminated, or a combination thereof can be selected in view of a variety of factors. For example, the power density of the electromagnetic radiation, the positive potential applied, the amount of time the first location is illuminated, or a combination thereof can be selected to control the rate of thinning and/or the extent to which the transition metal dichalcogenide material is thinned.

In some examples, the methods can further comprise illuminating a second location of the transition metal dichalcogenide material, wherein the transition metal dichalcogenide material has a thickness at the second location that is greater than a monolayer, thereby: promoting electrons from the valence band to the conduction band of the indirect band gap and decreasing the thickness of the transition metal dichalcogenide at the second location via electrochemical degradation, thereby thinning the transition metal dichalcogenide at the second location; wherein the method is self-limiting as the electrochemical degradation ceases when the thickness of the transition metal dichalcogenide at the second location is decreased to a monolayer, because the energy of the electromagnetic energy is insufficient to promote electrons from the valence band to the conduction band of the direct band gap. As used herein, “a second location” and “the second location” are meant to include any number of locations in any arrangement. Thus, for example “a second location” includes one or more second locations. In some embodiments, the second location can comprise a plurality of locations. In some embodiments, the second location can comprise a plurality of locations arranged in an ordered array.

Without wishing to be bound by theory, the thinning mechanism can be summarized as follows. The electromagnetic radiation pumps electrons from the valence band into the conduction band, e.g. across the indirect band gap, or the transition metal dichalcogenide material. The electrons are extracted out of the transition metal dichalcogenide material by applied the positive potential, leading to excessive holes in the transition metal dichalcogenide material. These holes can cause reaction of hydroxide ions (from the aqueous solution) and dangling metal atoms at the edges and at defect points of the transition metal dichalcogenide material, leading to oxidation of the transition metal dichalcogenide, thereby thinning the transition metal dichalcogenide material.

The substrate, the electromagnetic radiation source, the mirror, or a combination thereof can be translocated to illuminate the second location. As used herein translocating refers to any, type of movement about any axis (e.g., rotation, translation, etc.) In other words, as used herein, translocation refers to a change in position and/or orientation. In some examples, the translocation of the substrate, the electromagnetic radiation source, the mirror, or a combination thereof can be controlled by a computing device, wherein the computing device comprises a processor and a memory operably coupled to the processor, the memory having further computer-executable instructions stored thereon that, when executed by the processor, cause the processor to translocate the substrate, the electromagnetic radiation source, the mirror, or a combination thereof, such that the electromagnetic radiation source is configured to illuminate the second location.

The second location can, for example, be illuminated for an amount of time of 1 second or more (e.g., 2 seconds or more, 3 seconds or more, 4 seconds or more, 5 seconds or more, 10 seconds or more, 15 seconds or more, 20 seconds or more, 25 seconds or more, 30 seconds or more, 35 seconds or more, 40 seconds or more, 45 seconds or more, 50 seconds or more, 55 seconds or more, 1 minute or more, 1.5 minutes or more, 2 minutes or more, 2.5 minutes or more, 3 minutes or more, 3.5 minutes or more, 4 minutes or more, 4.5 minutes or more, 5 minutes or more, 6 minutes or more, 7 minutes or more, 8 minutes or more, or 9 minutes or more), In some examples, the second location can be illuminated for an amount of time of 10 minutes or less (e.g., 9 minutes or less, 8 minutes or less, 7 minutes or less, 6 minutes or less, 5 minutes or less, 4.5 minutes or less, 4 minutes or less, 3.5 minutes or less, 3 minutes or less, 2.5 minutes or less, 2 minutes or less, 1.5 minutes or less, 1 minute or less, 55 seconds or less, 50 seconds or less, 45 seconds or less, 40 seconds or less, 35 seconds or less, 30 seconds or less, 25 seconds or less, 20 seconds or less, 15 seconds or less, 10 seconds or less, 5 seconds or less, 4 seconds or less, 3 seconds or less, or 2 seconds or less). The amount of time the second location is illuminated can range from any of the minimum values described above to any of the maximum values described above. For example, the second location can be illuminated for an amount of time of from 1 second to 10 minutes (e.g., from 1 second to 1 minute, from 1 minute to 10 minutes, from 1 second to 5 minutes, from 5 minutes to 10 minutes, from 1 second to 150 seconds, from 1 second to 10 seconds, or from 100 seconds to 200 seconds).

In some examples, the methods comprise sequentially illuminating a plurality of locations by scanning the electromagnetic radiation across the transition metal dichalcogenide material; wherein the transition metal dichalcogenide material has a thickness at least a portion of the plurality of locations that is greater than a monolayer, said portion of the plurality of locations having a thickness that is greater than a monolayer being a first portion of the plurality of locations; thereby decreasing the thickness of the transition metal dichalcogenide at the first portion of the plurality of locations. The transition metal dichalcogenide material can, for example, be scanned in a raster manner. In some examples, the substrate is translocated to sequentially illuminate the plurality of locations; the electromagnetic radiation is provided by an electromagnetic radiation source, and the light source is translocated to sequentially illuminate the plurality of locations; the electromagnetic radiation is provided by an electromagnetic radiation source, the electromagnetic radiation source being configured to illuminate a mirror and the mirror is configured to reflect the electromagnetic radiation from the electromagnetic radiation source to illuminate the transition metal dichalcogenide material, and the mirror is translocated to illuminate the plurality of locations; or a combination thereof.

The electromagnetic radiation can, for example, be scanned across the transition metal dichalcogenide material at a rate of 0.1 microns (micrometer, μm) per second or more (e.g., 0.2 microns/second or more, 0.3 microns/second or more, 0.4 microns/second or more, 0.5 microns/second or more, 1 microns/second or more, 1.5 microns/second or more, 2 microns/second or more, 2.5 microns/second or more, 3 microns/second or more, 3.5 microns/second. or more, 4 microns/second or more, 4.5 microns/second. or more, 5 microns/second or more, 5.5 microns/second or more. 6 microns/second or more, 6.5 microns/second or more, 7 microns/second or more, 7.5 microns/second or more, 8 microns/second or more, 8.5 microns/second or more, 9 microns/second or more, or 9.5 microns/second or more). In some examples, the electromagnetic radiation can be scanned across the transition metal dichalcogenide material at a rate of 10 microns/second or less (e.g., 9.5 microns/second or less, 9 microns/second or less, 8.5 microns/second or less, 8 microns/second or less, 7.5 microns/second or less, 7 microns/second. or less, 6.5 microns/second or less, 6 microns/second or less, 5.5 microns/second or less, 5 microns/second or less, 4.5 microns/second or less, 4 microns/second or less, 3.5 microns/second or less, 3 microns/second or less, 2.5 microns/second or less, 2 microns/second or less, 1.5 microns/second or less, 1 microns/second or less, or 0.5 microns/second or less). The rate at which the electromagnetic radiation is scanned across the transition metal dichalcogenide material can range from any of the minimum values described above to any of the maximum values described above. For example, the electromagnetic radiation can be scanned across the transition metal dichalcogenide material at a rate of from 0.1 microns per second to 10 microns per second (e.g., from 0.1 microns/second to 1 micron/second, from 1 micron/second to 10 microns/second, from 0,1 microns/second to 3 microns/second, from 3 microns/second to 6 microns/second, from 6 microns/second to 10 microns/second, from 0.1 microns/second to 8 microns/second, from 1 micron/second to 10 microns/second, from 1 micron/second to 8 microns/second, or from 4 microns/second to 6 microns/second). In some examples, the electromagnetic radiation is scanned across the transition metal dichalcogenide material at a rate of 5 microns/second.

The electromagnetic radiation can, for example, be scanned across the transition metal dichalcogenide material for a total amount of time of 1 second or more (e.g., 2 seconds or more, 3 seconds or more, 4 seconds or more, 5 seconds or more, 10 seconds or more, 15 seconds or more, 20 seconds or more, 25 seconds or more, 30 seconds or more, 35 seconds or more. 40 seconds or more, 45 seconds or more, 50 seconds or more, 55 seconds or more, 1 minute or more, 1.5 minutes or more, 2 minutes or more, 2.5 minutes or more, 3 minutes or more, 3,5 minutes or more, 4 minutes or more, 4.5 minutes or more, 5 minutes or more, 6 minutes or more, 7 minutes or more, 8 minutes or more, or 9 minutes or more). In some examples, the electromagnetic radiation can be scanned across the transition metal dichalcogenide material for a total amount of time of 10 minutes or less (e.g., 9 minutes or less, 8 minutes or less, 7 minutes or less, 6 minutes or less, 5 minutes or less, 4.5 minutes or less, 4 minutes or less, 3.5 minutes or less, 3 minutes or less, 2.5 minutes or less, 2 minutes or less, 1.5 minutes or less, 1 minute or less, 55 seconds or less, 50 seconds or less, 45 seconds or less, 40 seconds or less, 35 seconds or less, 30 seconds or less, 25 seconds or less, 20 seconds or less, 15 seconds or less, 10 seconds or less, 5 seconds or less, 4 seconds or less, 3 seconds or less, or 2 seconds or less). The amount of time the electromagnetic radiation is scanned across the transition metal dichalcogenide material can range from any of the minimum values described above to any of the maximum values described above. For example, the electromagnetic radiation can be scanned across the transition metal dichalcogenide material for a total amount of time of from 1 second to 10 minutes e.g., e.g., from 1 second to 1 minute, from 1 minute to 10 minutes, from 1 second to 5 minutes, from 5 minutes to 10 minutes, from 1 second to 200 seconds, or from 100 seconds to 200 seconds).

In some examples, the transition metal dichalcogenide material has an area in the plane of the surface of the substrate and the thickness of the transition metal dichalcogenide material is decreased to a monolayer over the entire area of the transition metal dichalcogenide material in the plane of the surface of the substrate.

The methods can, for example, further comprise removing the thinned transition metal dichalcogenide material from the substrate, thereby creating a free-standing thinned transition metal dichalcogenide material. In some examples, the methods can further comprise depositing the free-standing thinned transition metal dichalcogenide material onto a second substrate.

Also disclosed herein are patterned transition metal dichalcogenide materials made using any of the methods disclosed herein. For example, the patterned transition metal dichalcogenide material can comprise one or more locations thinned (e.g., to a monolayer) using any of the methods disclosed herein.

Also disclosed herein are a monolayer of a transition metal dichalcogenide made using any of the methods disclosed herein. The monolayer can, for example, have a peak photoluminescence intensity of greater than that of a monolayer prepared using another method (e.g., via exfoliation).

In some examples, the monolayer has an area of 1 micrometer squared (μm²) or more (e.g., 5 μm² or more, 10 μm² or more, 15 μm² or more, 20 μm² or more, 25 μm² or more, 30 μm² or more, 35 μm² or more, 40 μm² or more, 45 μm² or more, 50 μm² or more, 60 μm² or more, 70 μm² or more, 80 μm² or more, 90 μm² or more, 100 μm² or more, 125 μm² or more, 150 μm² or more, 175 μm² or more, 200 μm² or more, 225 μm² or more, 250 μm² or more, 300 μm² or more, 350 μm² or more, 400 μm² or more, 450 μm² or more, 500 μm² or more, 600 μm² or more, 700 μm² or more, 800 μm² or more, 900 μm² or more, 1000 μm² or more, 1250 μm² or more, 1500 μm² or more, 1750 μm² or more, 2000 μm² or more, 2250 μm² or more, 2500 μm² or more, 2750 μm² or more, 3000 μm² or more, 3500 μm² or more, 4000 μm² or more, 4500 μm² or more, 5000 μm² or more, 6000 μm² or more, 7000 μm² or more, 8000 μm² or more, 9000 μm² or more. 1×10⁴ μm² or more, 2×10⁴ μm² or more, 3×10⁴ μm² or more, 4×10⁴ μm² or more, 5×10⁴ μm² or more, 6×10⁴ μm² or more, 7×10⁴ μm² or more, 8×10⁴ μm² or more, 9×10⁴ μm² or more, 1×10⁵ μm² or more, 2.5×10⁵ μm² or more, 5×10⁵ μm² or more, 7.5×10⁵ μm² or more, 1×10⁶ μm² or more, 2.5×10⁶ μm² or more, 5×10⁶ μm² or more, 7.5×10⁶ μm² or more, 1×10⁷ μm² or more, 2.5×10⁷ μm² or more, 5×10⁷ μm² or more, 7.5×10⁷ μm² or more ; 1×10⁸ μm² or more, 2.5×10⁸ μm² or more, 5×10⁸ μm² or more, 7.5×10⁸ μm² or more, 1×10⁹ μm² or more, 2.5×10⁹ μm² or more, 5×10⁹ μm² or more, 7.5×10⁹ μm² or more, 1×10¹⁰ μm² or more, 2.5×10¹⁰ μm² or more, or 5×10¹⁰ μm² or more).

In some examples, the monolayer has an area of 7×10¹⁰μm² or less e.g., 5×10¹⁰ μm² or less, 2.5×10¹⁰ μm² or less, 1×10¹⁰ μm² or less, 7.5×10⁹ μm² or less, 5×10⁹ μm² or less, 2.5×10⁹ μm² or less, 1×10⁹ μm² or less, 7.5×10⁸ μm² or less, 5×10⁸ μm² or less, 2.5×10⁸ μm² or less, 1×10⁸ μm² or less, 7.5×10⁷ μm² or less, 5×10⁷ μm² or less, 2.5×10⁷ μm² or less, 1×10⁷ μm² or less, 7.5×10⁶ μm² or less, 5×10⁶ μm² or less, 2.5×10⁶ μm² or less, 1×10⁶ μm² or less, 7.5×10⁵ μm² or less, 5×10⁵ μm² or less, 2.5×10⁵ μm² or less, 1×10⁵ μm² or less, 9×10⁴ μm² or less, 8×10⁴ μm² or less, 7×10⁴ μm² or less, 6×10⁴ μm² or less, 5×10⁴ μm² or less, 4×10⁴ μm² or less, 3×10⁴ μm² or less, 2×10⁴ μm² or less, 1×10⁴ μm² or less, 9000 μm² or less, 8000 μm² or less, 7000 μm² or less, 6000 μm² or less, 5000 μm² or less, 4500 μm² or less, 4000 μm² or less, 3500 μm² or less, 3000 μm² or less, 2750 μm² or less, 2500 μm² or less, 2250 μm² or less, 2000 μm² or less, 1750 μm² or less, 1500 μm² or less, 1250 μm² or less, 1000 μm² or less, 900 μm² or less, 800 μm² or less, 700 μm² or less, 600 μm² or less, 500 μm² or less, 450 μm² or less, 400 μm² or less, 350 μm² or less, 300 μm² or less, 250 μm² or less, 225 μm² or less, 200 μm² or less, 175 μm² or less, 150 μm² or less, 125 μm² or less, 100 μm² or less, 90 μm² or less, 80 μm² or less, 70 μm² or less, 60 μm² or less, 50 μm² or less, 45 μm² or less, 40 μm² or less, 35 μm² or less, 30 μm² or less, 25 μm² or less, 20 μm² or less, 15 μm² or less, or 10 μm² or less).

The area of the monolayer can range from any of the minimum values described above to any of the maximum values described above. For example, the monolayer can have an area of from 1 μm² to 7×10¹⁰ μm² (e.g., from 1 μm² to 1000 μm², from 1000 to 1×10⁶ μm², from 1×10⁶ μm² to 7×10¹⁰ μm², from 1 μm² to 1×10⁹ μm², from 1 μm² to 1×10⁷ μm² , from 1 μm² to 1×10⁵ μm², from 1 μm² to 5000 μm² , from 1000 μm² to 5000 μm² , from 1000 μm² to 3000 μm² , or from 2000 μm² to 3000 μm²).

Also disclosed herein are methods of use of the thinned transition metal dichalcogenide materials, the patterned transition metal dichalcogenide materials, the monolayer of the transition metal dichalcogenide, or a combination thereof, the methods comprising using the transition metal dichalcogenide material and/or the monolayer of the transition metal dichalcogenide in an electronic device, a photonic device, or a combination thereof.

Also disclosed herein are methods of use of the thinned transition metal dichalcogenide materials, the patterned transition metal dichalcogenide materials, the monolayer of the transition metal dichalcogenide, or a combination thereof, the methods comprising using the transition metal dichalcogenide material and/or the monolayer of the transition metal dichalcogenide in photodetection, valleytronics, sensing, biomedical imaging, drug delivery, or a combination thereof.

Also disclosed herein are systems for performing the methods described herein. Referring now to FIG. 1, the systems 100 for thinning a transition metal dichalcogenide material can comprise: a substrate 102 having a surface 104; a transition metal dichalcogenide material 106, a source electrode 108, and an aqueous solution 114 disposed on the surface 104 of the substrate 102; wherein the source electrode 108 is in electrical contact with the transition metal dichalcogenide material 106; wherein the transition metal dichalcogenide material 106 and the source electrode 108 are both submerged in the aqueous solution 114; a gate electrode 112 in electrochemical contact with the aqueous solution 114, wherein the gate electrode 112 is not in physical contact with the transition metal dichalcogenide material 106; a power source 130 connected to the source electrode 108 and the gate electrode 112, wherein the power source 130 is configured to apply a positive potential between the source electrode 108 and the gate electrode 112, thereby applying a positive potential between the transition metal dichalcogenide material 106 and the gate electrode 112; and an electromagnetic radiation source 140 configured to illuminate a first location 116 of the transition metal dichalcogenide material 106 with electromagnetic radiation.

When the thickness of the transition metal dichalcogenide material 106 at a location is a monolayer, then the transition metal dichalcogenide material 106 has a direct band gap; and when the thickness of the transition metal dichalcogenide material 106 at the location is greater than a monolayer, then the transition metal dichalcogenide material 106 has an indirect bandgap; wherein the indirect band gap has an energy that is the difference between a valence band and a conduction band; wherein the direct band gap has an energy that is the difference between a valence band and a conduction band; wherein the indirect band gap is lower in energy than the direct band gap.

The transition metal dichalcogenide material 106 has a thickness at the first location 116 that is greater than a monolayer, and the electromagnetic radiation has an energy that is less than the energy of the direct band gap and greater than or equal to the energy of the indirect band gap, such that when the first location 116 of the transition metal dichalcogenide material 106 is illuminated with the electromagnetic radiation from the electromagnetic radiation source 140 while the power source 130 applies the positive potential between the transition metal dichalcogenide material 106 and the gate electrode 112, then: electrons are promoted from the valence band to the conduction band of the indirect band gap and the thickness of the transition metal dichalcogenide at the first location 116 is decreased via electrochemical degradation, thereby thinning the transition metal dichalcogenide at the first location 116; wherein the thinning is self-limiting as the electrochemical degradation ceases when the thickness of the transition metal dichalcogenide at the first location 116 is decreased to a monolayer, because the energy of the electromagnetic energy is insufficient to promote electrons from the valence band to the conduction band of the direct band gap.

In some examples, the system 100 can include a single electromagnetic radiation source 140. In other examples, more than one electromagnetic radiation source 140 can be included in the system 100. The electromagnetic radiation source 140 can be any type of electromagnetic radiation source. Examples of suitable electromagnetic radiation sources include natural sources (e.g., sunlight) and artificial sources (e.g., incandescent light bulbs, light emitting diodes, gas discharge lamps, arc lamps, lasers etc.). In some examples, the electromagnetic radiation source 140 is a laser.

The system 100 can, in some examples, further comprise a means for translocating the substrate 102 and/or the electromagnetic radiation source 140.

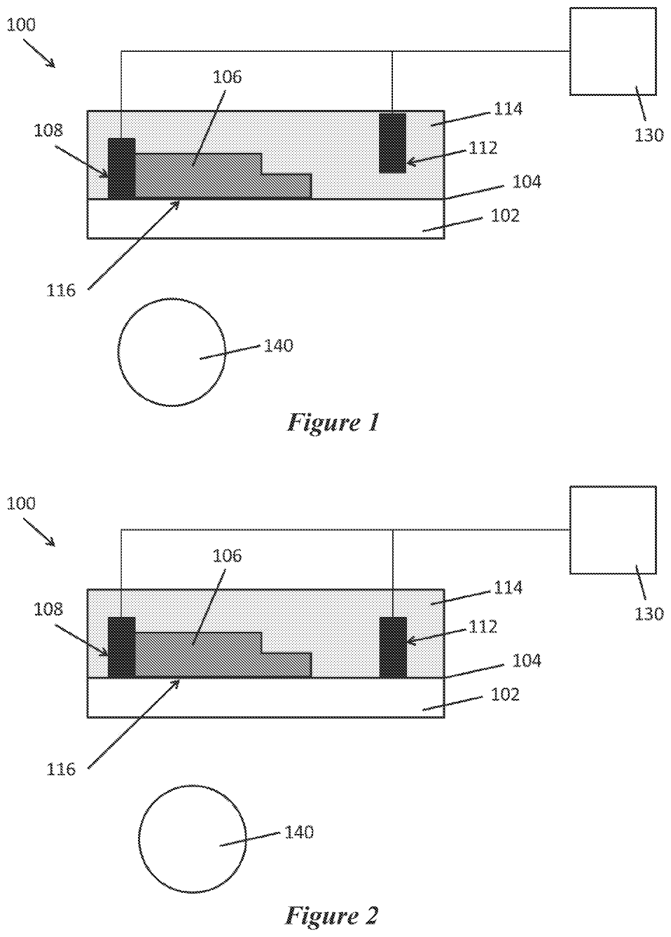

Referring now to FIG. 2, the gate electrode 112 can in some examples be disposed on the surface 104 of the substrate 102, such that the gate electrode 112 is submerged in the aqueous solution 114.

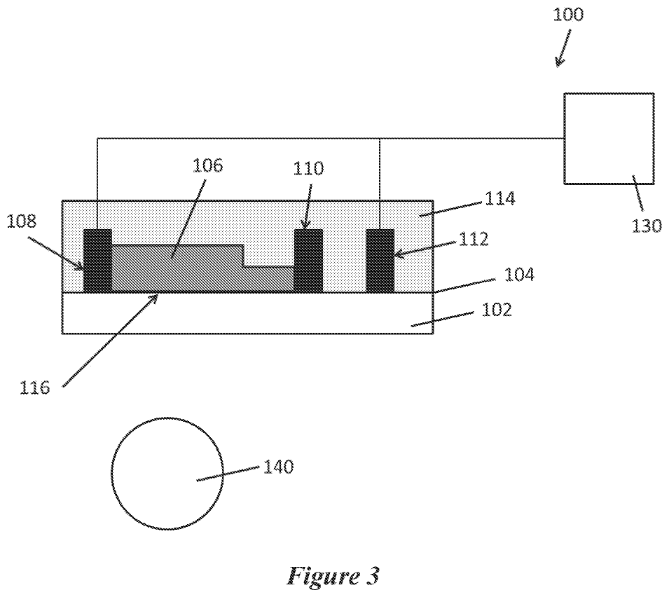

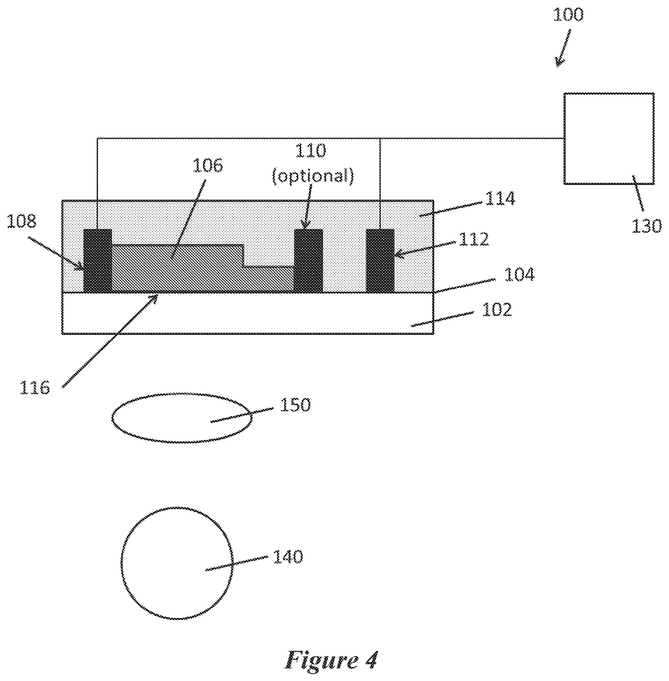

Referring now to FIG. 3, the system 100 can, in some examples, further comprise a drain electrode 110 disposed on the surface 104 of the substrate 102, wherein the drain electrode 110 is in electrical contact with the transition metal dichalcogenide material 106 and is submerged in the aqueous solution 114. Referring now to FIG. 4, the systems 100 can, in some examples, further comprise a lens 150. The lens can be any type of lens, such as a simple lens, a compound lens, a spherical lens, a toric lens, a biconvex lens, a plano-convex lens, a plano-concave lens, a negative meniscus lens, a positive meniscus lens, a biconcave lens, a converging lens, a diverging lens, a cylindrical lens, a Fresnel lens, a lenticular lens, or a gradient index lens.

In some examples, the lens 150 can comprise a microscope objective. In some examples, the system 100 can include a single lens 150. In other examples, more than one lens 150 can be included in the system 100.

The system 100 can, in some examples, be configured such that electromagnetic radiation from the electromagnetic radiation source 140 traverses the lens 150 and the substrate 102 to illuminate the first location 116 of the transition metal dichalcogenide material 106, for example as shown in FIG. 4. The lens 150 can, for example, be configured to focus the electromagnetic radiation from the electromagnetic radiation source.

In some examples, the system 100 further comprises an inverted microscope having a stage, wherein the substrate 102 is mounted on the stage of the inverted microscope and the lens 150 comprises a microscope objective. In some examples, the system 100 further comprises an uptight microscope having a stage, wherein the substrate 102 is mounted on the stage of the upright microscope.

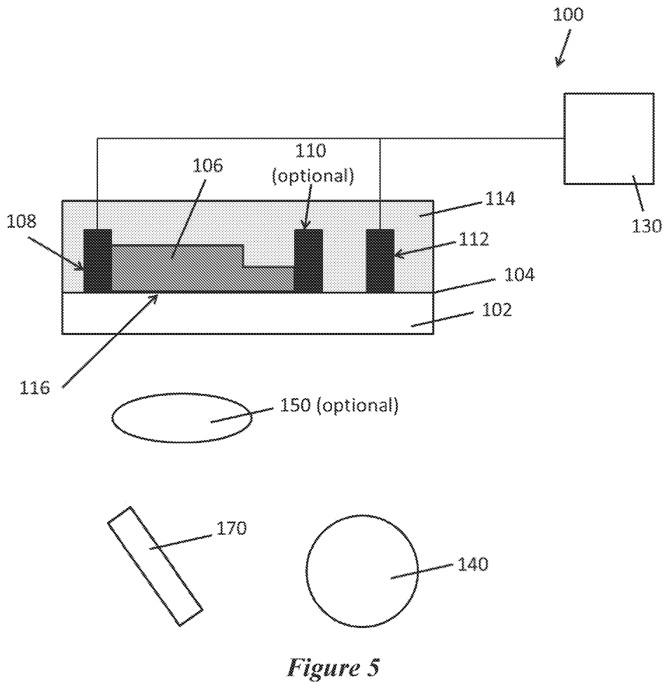

Referring now to FIG. 5, the systems 100 can, in some examples further comprise a mirror 170, wherein the system 100 is aligned such that the electromagnetic radiation source 140 is configured to illuminate the mirror 170 and the mirror 170 is configured to reflect the electromagnetic radiation from the electromagnetic radiation source 140 to illuminate the first location 116. In some examples, the system 100 can further comprise a means for translocating the mirror 170. In some examples, the mirror 170 can comprise a plurality of mirrors (e.g., a digital micromirror device).

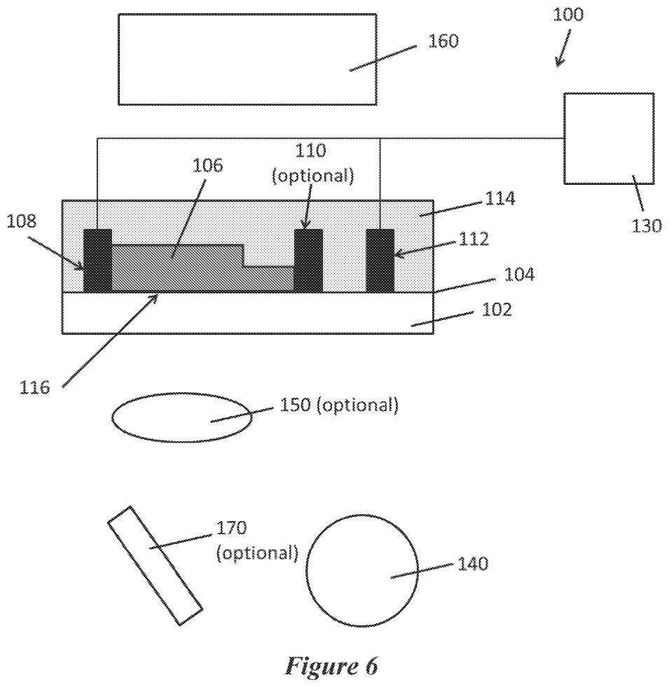

Referring now to FIG. 6, the systems 100 can, in some examples, further comprise an instrument 160 configured to capture an electromagnetic signal from the transition metal dichalcogenide material 106. The instrument 160 can, for example, comprise a camera, an optical microscope, an electron microscope, a spectrometer, or combinations thereof. Examples of spectrometers include, but are not limited to, Raman spectrometers, UV-vis absorption spectrometers, IR absorption spectrometers, fluorescence spectrometers, photoluminescence spectrometers, and combinations thereof.

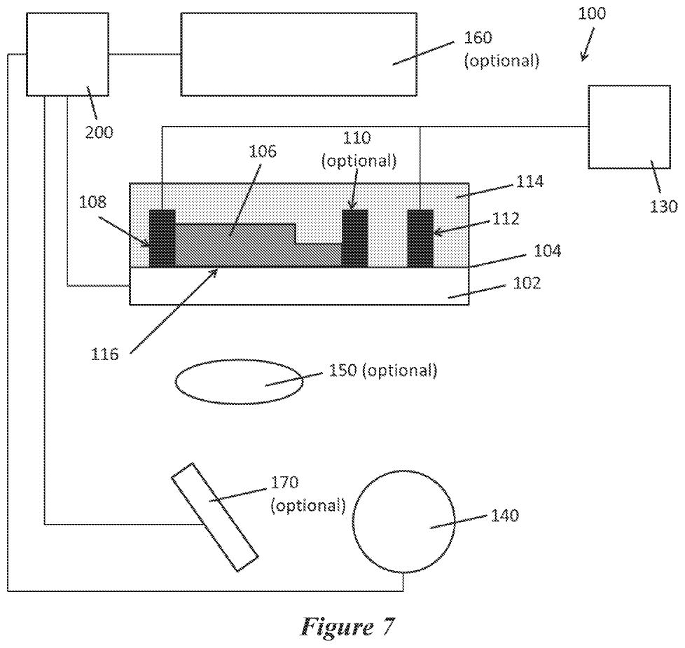

In some examples, the systems 100 can further comprise a computing device 200 configured to: receive, process, and output electromagnetic signals from the instrument 160; send control signals to the means for translocating the substrate 102, the means for translocating the electromagnetic radiation source 140, the means for translocating the mirror 170, or a combination thereof; or a combination thereof, for example as shown in FIG. 7.

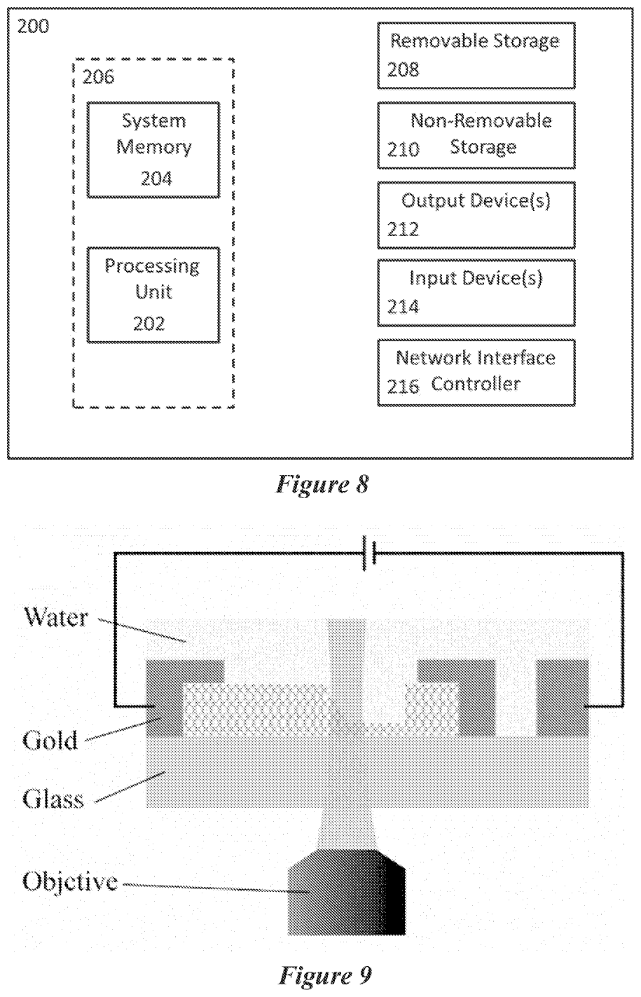

FIG. 8 illustrates an example computing device 200 upon which examples disclosed herein may be implemented, The computing device 200 can include a bus or other communication mechanism for communicating information among various components of the computing device 200. In its most basic configuration, computing device 200 typically includes at least one processing unit 202 (a processor) and system memory 204. Depending on the exact configuration and type of computing device, system memory 204 may be volatile (such as random access memory (RAM)), non-volatile (such as read-only memory (ROM), flash memory, etc.), or some combination of the two. This most basic configuration is illustrated in

FIG. 8 by a dashed line 206. The processing unit 202 may be a standard programmable processor that performs arithmetic and logic operations necessary for operation of the computing device 200.

The computing device 200 can have additional features/functionality. For example, computing device 200 may include additional storage such as removable storage 208 and non-removable storage 210 including, but not limited to, magnetic or optical disks or tapes. The computing device 200 can also contain network connection(s) 216 that allow the device to communicate with other devices. The computing device 200 can also have input device(s) 214 such as a keyboard, mouse, touch screen, antenna or other systems configured to communicate with the camera in the system described above, etc. Output device(s) 212 such as a display, speakers, printer, etc. may also be included. The additional devices can be connected to the bus in order to facilitate communication of data among the components of the computing device 200.

The processing unit 202 can be configured to execute program code encoded in tangible, computer-readable media. Computer-readable media refers to any media that is capable of providing data that causes the computing device 200 (i.e., a machine) to operate in a particular fashion. Various computer-readable media can be utilized to provide instructions to the processing unit 202 for execution. Common forms of computer-readable media include, for example, magnetic media, optical media, physical media, memory chips or cartridges, a carrier wave, or any other medium from which a computer can read. Example computer-readable media can include, but is not limited to, volatile media, non-volatile media and transmission media.

Volatile and non-volatile media can be implemented in any method or technology for storage of information such as computer readable instructions, data structures, program modules or other data and common forms are discussed in detail below. Transmission media can include coaxial cables, copper wires and/or fiber optic cables, as well as acoustic or light waves, such as those generated during radio-wave and infra-red data communication. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In an example implementation, the processing unit 202 can execute program code stored in the system memory 204. For example, the bus can carry data to the system memory 204, from which the processing unit 202 receives and executes instructions. The data received by the system memory 204 can optionally be stored on the removable storage 208 or the non-removable storage 210 before or after execution by the processing unit 202.

The computing device 200 typically includes a variety of computer-readable media. Computer-readable media can be any available media that can be accessed by computing device 200 and includes both volatile and non-volatile media, removable and non-removable media. Computer storage media include volatile and non-volatile, and removable and non-removable media implemented in any method or technology for storage of information such as computer readable instructions, data structures, program modules or other data. System memory 204, removable storage 208, and non-removable storage 210 are all examples of computer storage media. Computer storage media include, but are not limited to, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by computing device 200. Any such computer storage media can be part of computing device 200.

It should be understood that the various techniques described herein can be implemented in connection with hardware or software or, where appropriate, with a combination thereof. Thus, the methods, systems, and associated signal processing of the presently disclosed subject matter, or certain aspects or portions thereof, can take the form of program code (i.e., instructions) embodied in tangible media, such as floppy diskettes, CD-ROMs, hard drives, or any other machine-readable storage medium wherein, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs can implement or utilize the processes described in connection with the presently disclosed subject matter, e.g., through the use of an application programming interface (API), reusable controls, or the like. Such programs can be implemented in a high level procedural or object-oriented programming language to communicate with a computer system. However, the program(s) can be implemented in assembly or machine language, if desired. In any case, the language can be a compiled or interpreted language and it may be combined with hardware implementations.

In certain examples, the system memory 204 comprises computer-executable instructions stored thereon that, when executed by the processor 202, cause the processor 202 to receive an electromagnetic signal from the instrument 160; process the electromagnetic signal to obtain a characteristic of the transition metal dichalcogenide material 106; and output the characteristic of the transition metal dichalcogenide material 106, In some examples, the electromagnetic signal received by the processor from the instrument can comprise an image, a spectrum (e.g., Raman, LV-vis, IR, fluorescence, photoluminescence), a micrograph, or combinations thereof. The characteristic of the transition metal dichalcogenide material can comprise, for example, the photoluminescence of the transition metal dichalcogenide material; the thickness of the transition metal dichalcogenide material; or a combination thereof.

The analysis of signals captured by the instrument can be carried out in whole or in part on one or more computing device(s). For example, the system may comprise one or more additional computing device.

In certain examples, the system memory 204 comprises computer-executable instructions stored thereon that, when executed by the processor 202, cause the processor 202 to send a control signal to the means for translocating the substrate 102, the means for translocating the electromagnetic radiation source 140, the means for translocating, the mirror 170, or a combination thereof, thereby: translocating the substrate 102 the electromagnetic radiation source 140, the mirror 170, or a combination thereof, such that the electromagnetic radiation source 140 is configured to illuminate the transition metal dichalcogenide material 106 at a second location while the power source 130 is configured to apply the positive potential between the transition metal dichalcogenide material 106 and the gate electrode 112, wherein the transition metal dichalcogenide material 106 has a thickness at the second location that is greater than a monolayer; such that when the second location of the transition metal dichalcogenide material 106 is illuminated with the electromagnetic radiation from the electromagnetic radiation source 140 while the power source 130 applies the positive potential between the transition metal dichalcogenide material 106 and the gate electrode 112, then: electrons are promoted from the valence band to the conduction band of the indirect band gap and the thickness of the transition metal dichalcogenide at the second location is decreased via electrochemical degradation, thereby thinning the transition metal dichalcogenide at the second location; wherein the thinning is self-limiting as the electrochemical degradation ceases when the thickness of the transition metal dichalcogenide at the second location is decreased to a monolayer, because the energy of the electromagnetic energy is insufficient to promote electrons from the valence band to the conduction band of the direct band gap.

In certain examples, the system memory 204 comprises computer-executable instructions stored thereon that, when executed by the processor 202, cause the processor 202 to send a control signal to the means for translocating the substrate 102, the means for translocating the electromagnetic radiation source 140, the means for translocating the mirror 170, or a combination thereof, thereby: translocating, the substrate 102, the electromagnetic radiation source 140, the mirror 170, or a combination thereof, such that the electromagnetic radiation source 140 is configured to sequentially illuminate the transition metal dichalcogenide material 106 at a plurality of locations by scanning the electromagnetic radiation across the transition metal dichalcogenide material 106 while the power source 130 is configured to apply the positive potential between the transition metal dichalcogenide material 106 and the gate electrode 112, wherein the transition metal dichalcogenide material 106 has a thickness at least a portion of the plurality of locations that is greater than a monolayer, said portion of the plurality of locations having a thickness that is greater than a monolayer being a first portion of the plurality of locations; thereby decreasing the thickness of the transition metal dichalcogenide at the first portion of the plurality of locations.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the systems and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1

### Optoelectronic Thinning of Transition Metal Dichalcogenides for Device Fabrication

Abstract. Atomically thin transition metal dichalcogenides (IMDCs) are promising materials for nanodevices due to their electronic, optoelectronic, and mechanical properties. However, massive production of high-quality atomic monolayers of transition metal dichalcogenides remains challenging. Herein, a self-limiting optoelectronic thinning method for fabrication of monolayers of transition metal di chalcogenides and their micro/nanopatterns at the large scale and in a versatile manner is reported. By properly choosing the wavelength of the working laser beams, electrons were selectively excited between the valence band and the conduction band of the indirect band gap of bulk or few-layer MoS₂, which promoted the thinning of the transition metal dichalcogenides via electrochemical degradation. Once the thickness of the MoS₂ reached an atomic monolayer, the laser beam could not excite the electrons over the wider direct band gap. Therefore, the electrochemical reaction stopped and the MoS₂ remained as an atomic monolayer.

Introduction. Atomically thin two-dimensional (2D) materials have been of interest since the discovery of the field effect of graphene (Novoselov et al. Science, 2004, 306(696), 666-669). Unlike graphene which has a zero-band-gap (Novoselov et al. Nature, 2012, 490(7419), 192-200), atomic monolayers of transition metal dichalcogenides (IMDCs) such as MoS₂, WS₂, MoSe₂, and WSe₂ feature a direct band gap (Manzeli et al, Nat. Rev. Mater., 2017, 2, 17033). With their excellent electrical and optical properties, robust mechanical deformation, large surface-to-volume ratio, strong spin-orbit coupling and spin-valley locking, atomically thin transition metal dichalcogenides are promising for applications in photodetection, valleytronics, sensing, biomedical imaging, and drug delivery.

Many methods have been developed to obtain atomic monolayers of transition metal dichalcogenides, including mechanical exfoliation (Huang et al, ACS Nano, 2015, 9(11), 10612-10620), liquid-phase exfoliation (Coleman et al. Science, 2011, 331(6017), 568-571), electrochemical deposition (Wan et al., Adv. Fund. Mater., 2017, 2(19), 1603998), chemical vapor deposition (CND) (Lee et al., Adv. Mater., 2012, 24(17), 2320-2325), and molecular beam epitaxy (MBE) (Roy et al. ACS Appl. Mater. Interfaces, 2016, 8(11), 7396-7402). However, the mechanical exfoliation method is not scalable and usually obtains monolayers of small sizes. The liquid-phase exfoliation can cause unwanted phase change of the transition metal dichalcogenide. Molecular beam epitaxy and chemical vapor deposition can achieve sizable monolayers of transition metal dichalcogenides. However, the electrical properties of transition metal dichalcogenides grown by bottom-up approaches, such as molecular beam epitaxy and chemical vapor deposition, are not as good as those by top-down methods. Molecular beam epitaxy and chemical vapor deposition also require complex and expensive instruments.

Recently, laser-thinning has been demonstrated as a different top-down approach towards thinning bulk flakes of transition metal dichalcogenides to atomic monolayers (Lu et al, Nanoscale, 2013,5(19), 8904-8908; Liu et al., ACS Nano, 2013, 7(5), 4202-4209; Wu et al., Small, 2013, 9(19), 3314-3319; Hoffman et al. ACS Appl. Mater. Interfaces, 2020, 12(6), 7345-7350; Zhang et al, Adv. Funct. Mater., 2017, 27(41), 1-12). Laser thinning is particularly promising because of its capability of low-cost, site-selective, and on-demand patterning of atomic layers of transition metal dichalcogenides. Castellanos-Gomez et al. demonstrated laser thinning of MoS₂ through lateral thermal sublimation induced by a high-fluence laser beam (30-80 mW/μm²) (Castellanos-Gomez et al. Nano Len., 2012, 12(6), 3187-3192). The bottom atomic layer of MoS₂ was preserved because of the thermal sink effect of the substrate (Castellanos-Gomez et al. Nano Lett., 2012,12(6), 3187-3192). However, the high temperature could cause a phase transition that can negatively affect the properties of the resulting monolayers (Cho et al. Science, 2015, 349(6248), 625-628).

Alternatively, laser thinning can occur through optically promoted chemical reactions at the laser-irradiated site of transition metal dichalcogenide films, which usually requires lower temperatures. For example, laser-induced thermal oxidation was used for thinning of MoS₂ at relatively low temperature (330° C.) (Wu et al., Small, 2013, 9(19), 3314-3319). However, this opto-thermal oxidation method is limited to thinning 2-4 layers of flakes into an atomic monolayer. Nagareddy et al. conducted layer-by-layer thinning of a MoTe₂ flake using a low laser fluence (0.3-4 mW/μm²) in cooperation with adsorbed water vapor on the flake surface (Nagareddy et al. Adv. Funct. Mater., 2018, 28(52), 1804434). The removal process was partly due to the weak thermal and chemical stability of MoTe₂ (Zhu et al. ACS Nano, 2017, 11(11), 11005-11014), which means this process is not applicable to materials with stronger interatomic bonding like MoS₂ and WS₂.

Laser-induced electrochemical thinning of MoS₂ was also performed by Sunamura et al. (Sunamura et al, J. Mater. Chem. C, 2016, 4(15), 3268-3273). By applying a 532 nm laser beam to excite electrons from the valance band to the conduction band over the direct band gap of hulk MoS₂, the researchers initiated electrochemical degradation at one edge of the MoS₂ at a constant voltage of 0 V in an electrolyte solution (1 mM phosphate buffer) (Sunamura et al. J. Mater. Chem. C, 2016, -1(15), 3268-3273). Electrochemical reactions were believed to occur due to an increased current during the thinning process. Thinning the MoS₂ from hulk to monolayer was achieved with a 2.77 mW, 532 nm laser beam. A higher-efficient thinning was demonstrated at an elevated electric potential (Wu et al. 2D Mater., 2019, 6(4), 045052). By applying a 0.1 V electrochemical potential and 94 nW/μm², 660 nm laser illumination, a MoS₂ flake with a surface area of 10,000 μm² and a thickness of 100 nm was thinned to a monolayer within 4 s. It was believed that the higher exciton binding energy in the monolayer slowed down the chemical reaction and thus the thinning process. Despite this slow down, the thinning process should be immediately stopped upon reaching a monolayer thickness to avoid potential damage to the 2D MoS₂ (e.g., the monolayer MoS₂), which would require in-situ metrology and efficient optical/electrical control with a feedback loop.

Herein, a self-limiting optoelectronic thinning method is reported where an optically activated electrochemical reaction will stop automatically once the transition metal dichalcogenide flakes are thinned into monolayers. Monolayers of MoS₂ with qualities as good as mechanically exfoliated ones have been obtained without elaborate control of experimental conditions. Furthermore, the monolayers can be patterned by controlling the laser beam to drive the site-selective chemical reaction. With the capability of robust thinning, arbitrary patterning, and self-limiting behavior, the optoelectronic method can enable mass production and patterning of high-quality monolayers of transition metal dichalcogenides for electronic and photonic nanodevices.

### Results and Discussion

Thinning Results. Thick MoS₂ flakes were exfoliated from natural hulk crystals and transferred onto Si/SiO₂ substrates using a gold-assisted exfoliation technique (Desai et al. Adv. Mater, 2016, 28(21), 4053-4058), These flakes were then transferred onto clean glass slides Ti/Au electrodes (2 nm/50 nm in thickness) were created at the flakes by a standard photolithographic process (FIG. 9). The samples were mounted on an inverted microscope and immersed in deionized (DI) water. The optoelectronic thinning process was initialed when a positive potential was applied between the MoS₂ flake and the gate electrode, and a 785 nm laser beam was directed onto the edge of the flake, as illustrated in FIG. 9.

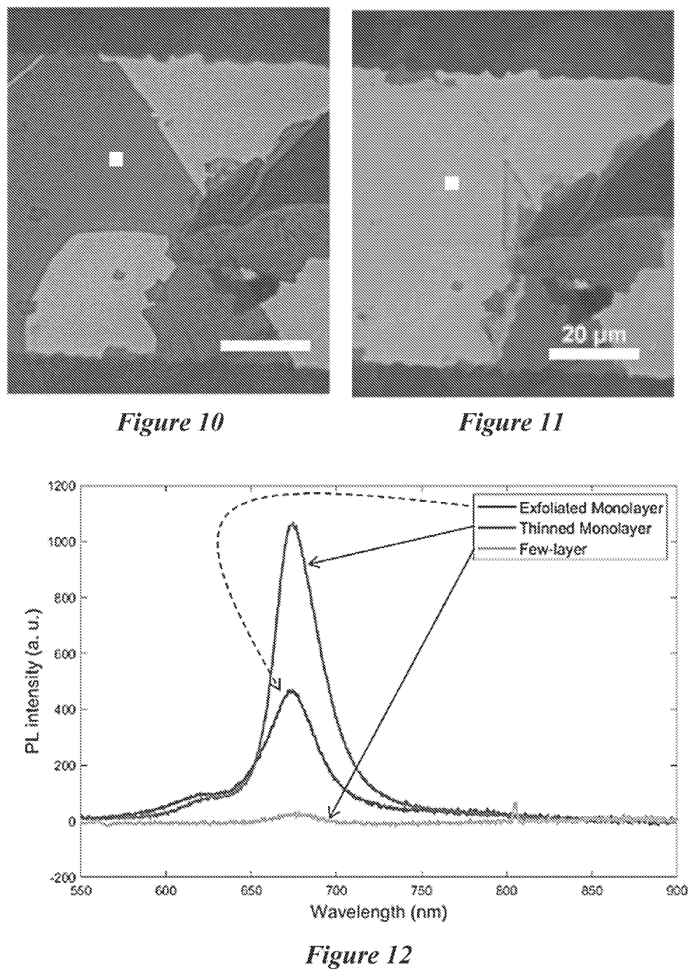

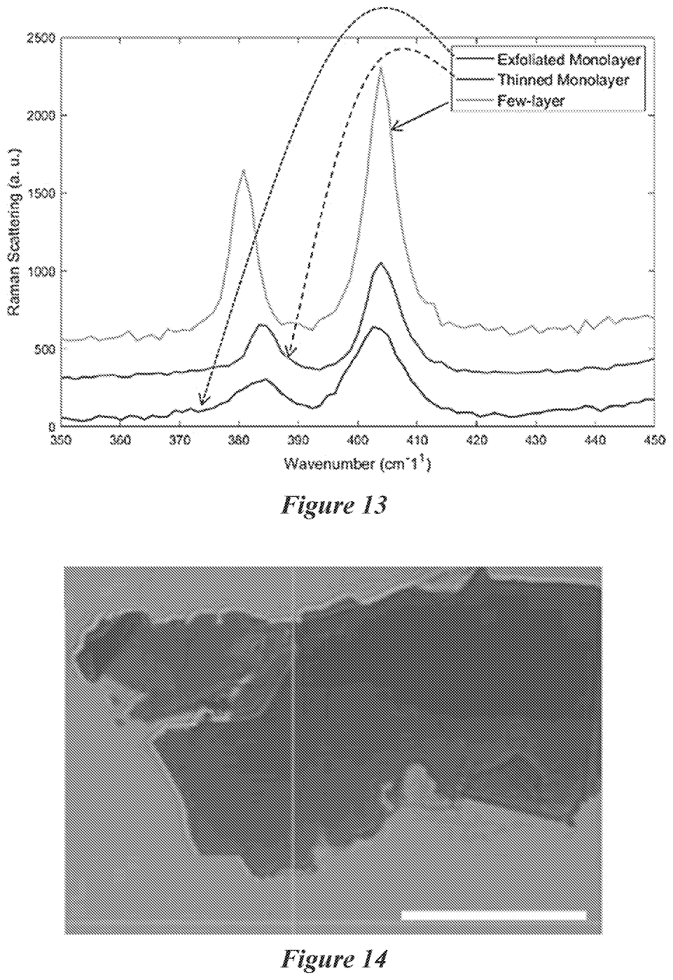

A few-layer MoS₂ flake ˜2500 μm² in area was scanned for 150 seconds by a 785 nm laser with ˜5 mW/μm² fluence while a 0.5 V potential was applied. FIG. 10 and FIG. 11 show the flake before and after the thinning, respectively. The monolayer of MoS₂ after the thinning was verified by the strong photoluminescence spectrum (PL) and Raman spectrum (Li et al. Adv. Fund. Mater., 2012, 22(7), 1385-1390), as shown in FIG. 12 and FIG. 13. Compared to exfoliated few-layer MoS₂, monolayers (both exfoliated and thinned) exhibit stronger photoluminescence and a smaller separation between the E¹_{2g} and E_{1g} Raman modes. The thinned monolayer had the strongest photoluminescence intensity, which indicates the thinned monolayer has the highest quality. The thinning process was initiated from the flake edges, which is similar to other low-power laser thinning methods (Parzinger et al. ACS Nano, 2015, 9(11), 11302-11309). The thinning process can be sped up by increasing the potential or the laser power.

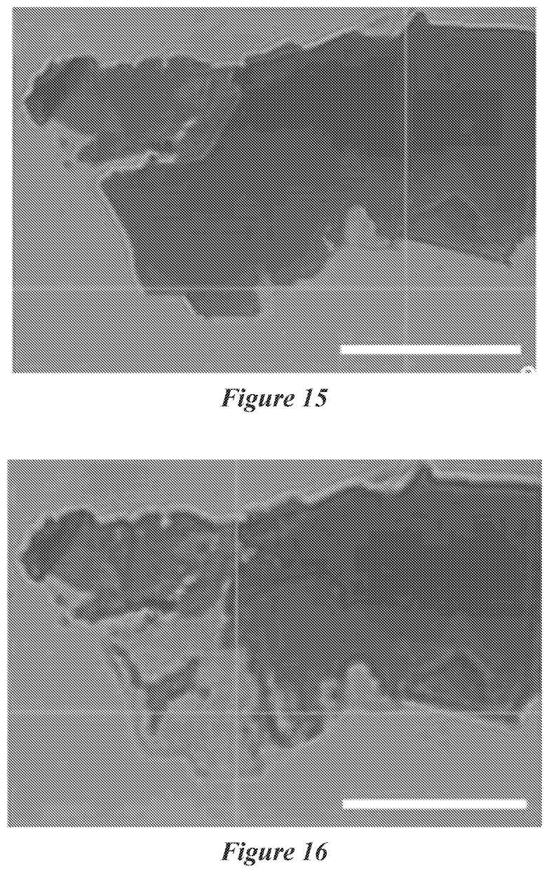

Thinning mechanism. To explore the optoelectronic thinning mechanism, several control experiments were conducted. Firstly, the role of the laser beam in the thinning was tested. No obvious change was observed on a flake after it was kept in darkness (FIG. 14) and under 1.0 V potential voltage for 15 mins (FIG. 15). Once the laser was turned on, rapid thinning occurred; FIG. 16 shows the same biased flake after being irradiated by a 785 nm laser beam for 4 seconds. When the electrodes were disconnected from the power station, the flake connected to the electrodes was thinned more slowly, as shown in FIG. 17 and FIG. 18. In contrast, for flakes not connected to any electrodes, no thinning was observed even when high laser power was applied (˜50 mW/μm²). Also, no thinning was observed when a negative potential was applied.

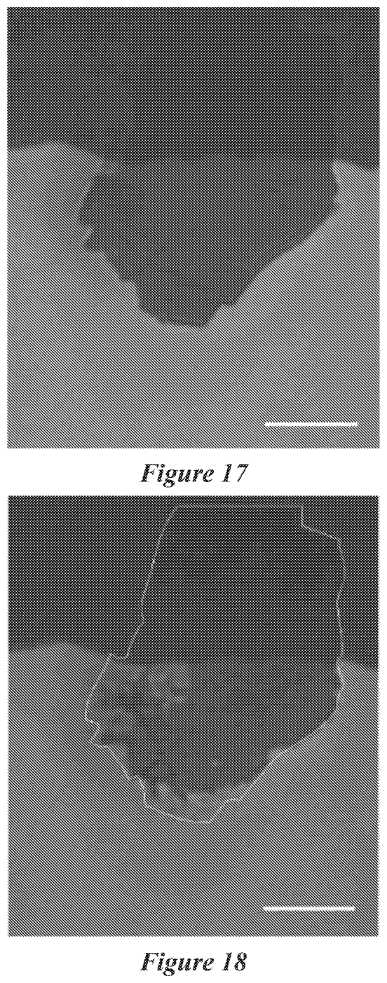

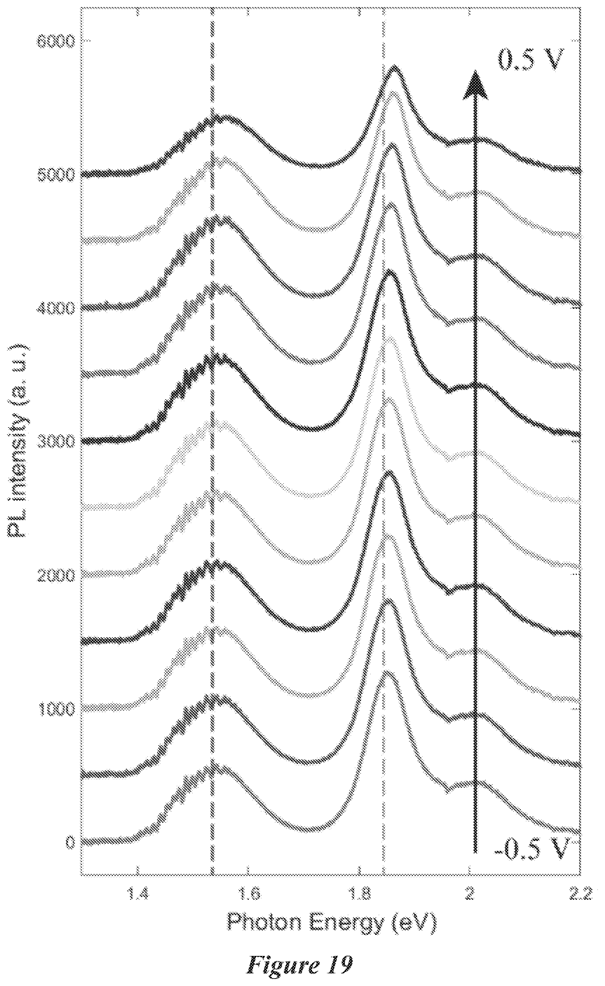

To further study the role of electric potential, photoluminescence spectra for a bilayer MoS₂ sheet were measured with the potential varied from −0.5 V to 0.5 V (FIG. 19). The photoluminescence peak at ˜1.55 eV (˜800 nm) arises from the indirect band (IX) of the bilayer, the peak at ˜1.86 eV (˜667 nm) is a combination of neural A excitons (A⁰) and negatively charged trions (A⁻), and the peak at ˜2.05 eV (˜605 nm) is from B excitons (B) (FIG. 19) (Mak et al. Phys. Rev. Lett., 2010, 105(13), 2-5). As the potential changed from −0.5 V to 0.5 V, a slightly blue shift of the middle peak (i.e., ˜1.86 eV) occurred. This shift was more prominent in monolayers. This shift is due to a trion-to-A-exciton transition caused by the positive potential (Pei et al. Small, 2015, 1448), 6384-6390). The relatively weaker transition in the bilayer is because the applied electric field mainly tunes the optically excited electron density in the A valley with a minor change in the K - valley. No shift occurred to the 1.55 eV peak because the indirect trions have lower binding energies than the direct ones (Oilman et al, Nano Lett., 2020, 20(3), 1869-1875).

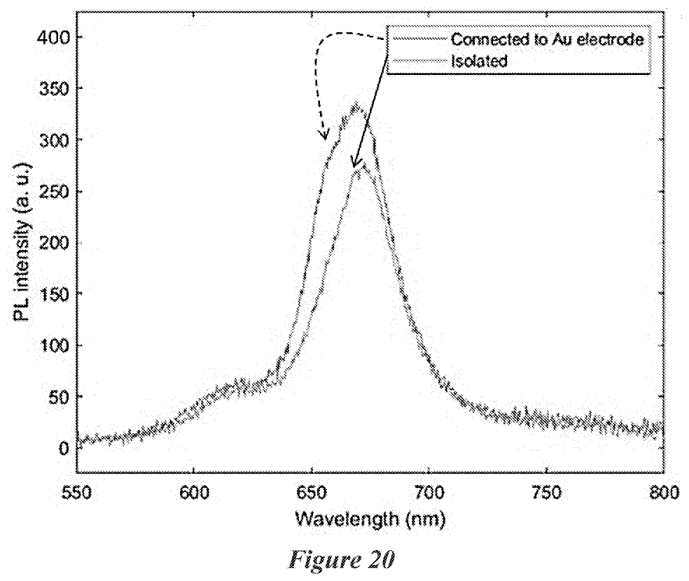

The tuning of optically excited electron density by the applied electric field is revealed by the photoluminescence intensity change from A excitons and direct trions. To explain the degradation of MoS₂ flakes that were in contact with Au without any bias, photoluminescence spectra of MoS₂ monolayers were measured as shown in FIG. 20. A transition from trions to A excitons is revealed, which arises from the lower Fermi energy of Au than the MoS₂ conduction band (McDonnell et al. ACS Nano, 2014, 8(3), 2880-2888; Kaushik et al Appl. Phys. Lett., 2014, 105(11), 1-5; Yin et al. Mater. Lett., 2019, 255, 126531). As a result, optically excited electrons in MoS₂ can be transferred into Au electrodes, leaving holes in the MoS₂.

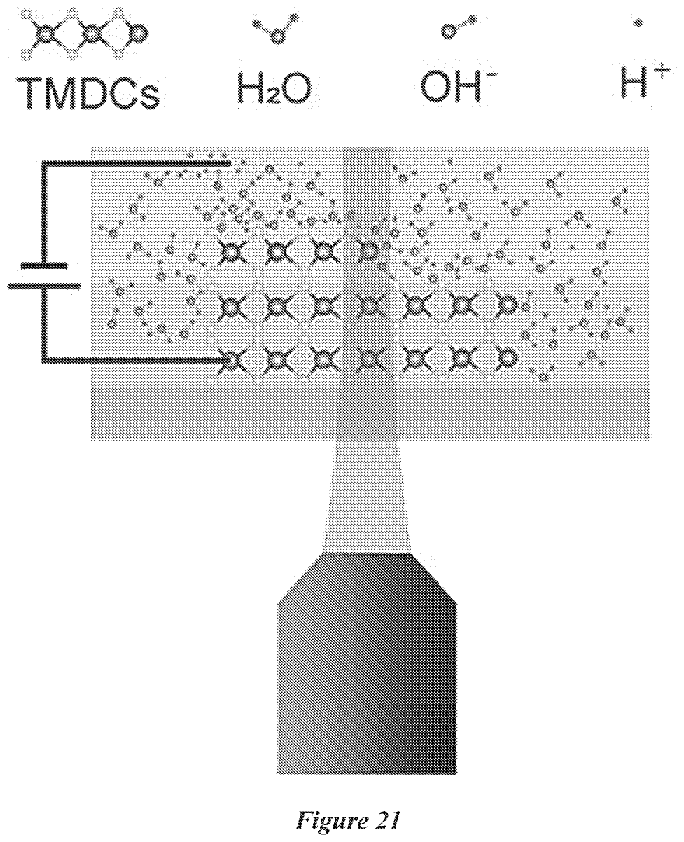

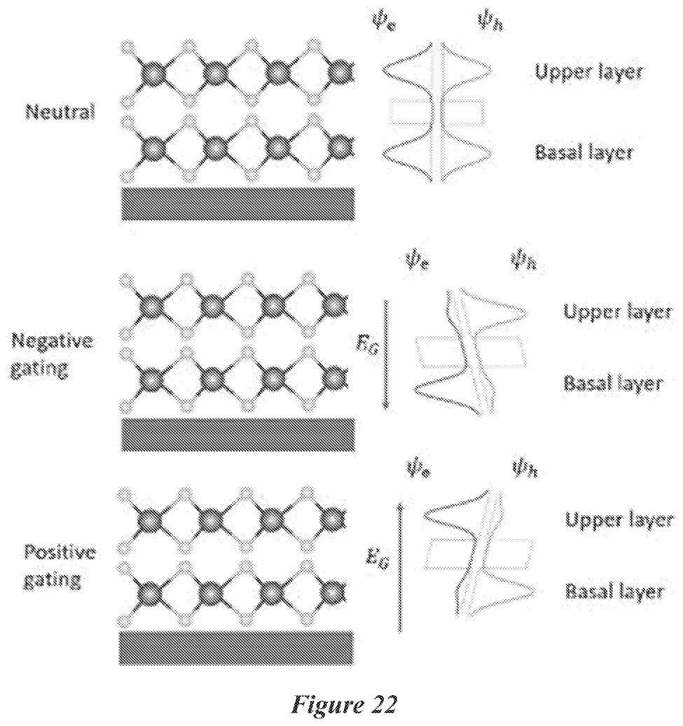

The thinning mechanism can thus be summarized as follows. A laser beam pumps electrons from the valence band into the conduction band of MoS₂. The electrons are extracted out of the transition metal dichalcogenide by a positive bias, leading to excessive holes in the transition metal dichalcogenide. These holes cause reaction of hydroxide ions (from DI water) and dangling metal atoms at the MoS₂ flake edges and defect points, leading to oxidation of MoS₂ (Parzinger et al. ACS Nano, 2015, 9(11), 11302-11309; Sivaram et al. ACS Appl. Mater. Interfaces, 2019, 11(17), 16147-16155; Rho et al. ACS Appl. Mater. Interfaces, 2019, 11(42), 39385-39393). The thinning mechanism is illustrated in FIG. 21. Under a vertical electric field, the optically excited electrons and holes will be redistributed, as shown in FIG. 22. When a negative gating (i.e., positive potential) is applied to a flake, more electrons are driven to the bottom layer, which lowers the degradation rate of this layer and thus improves the quality of the final monolayer.

Self-limiting. The importance of self-limiting in the thinning process and how the optoelectronic thinning can achieve the self-limiting is highlighted next.

Though the higher-density electrons in the bottom layer under an external bias slow down the chemical reaction rate at this layer, an elaborate control of the laser power, potential voltage, and scanning speed of the laser beam is still needed to protect the monolayer when one uses a laser beam to pump electrons over a direct band gap, as shown in the previous laser thinning (Sunamura et al. J. Mater. Chem. C, 2016, 4(15), 3268-3273; Wu et al. 2D Mater., 2019, 6(4), 045052; Parzinger et al. ACS Nano, 2015, 9(11), 11302-11309; Sivaram et al., ACS Appl. Mater. Interfaces, 2019, 1417), 16147-16155). If any of the experimental conditions was not optimized, the thinning would fail with all the layers being totally removed.

MoS₂ undergoes a transition from an indirect to a direct bandgap semiconductor in the single layer limit. The indirect band gap of MoS₂ varies with the thickness (e.g., from ˜1.55 eV (˜800 μm) for bilayer MoS₂ to 1.2 eV (˜1033 nm) for multilayer or bulk MoS₂) while the direct band gap of monolayer MoS₂ is ˜1.9 eV (˜650 nm).

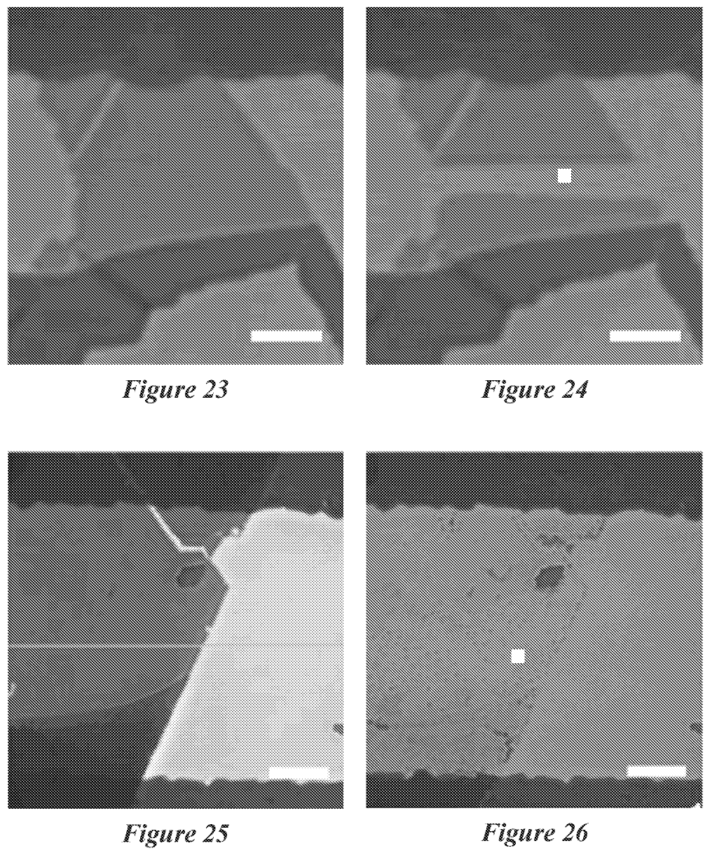

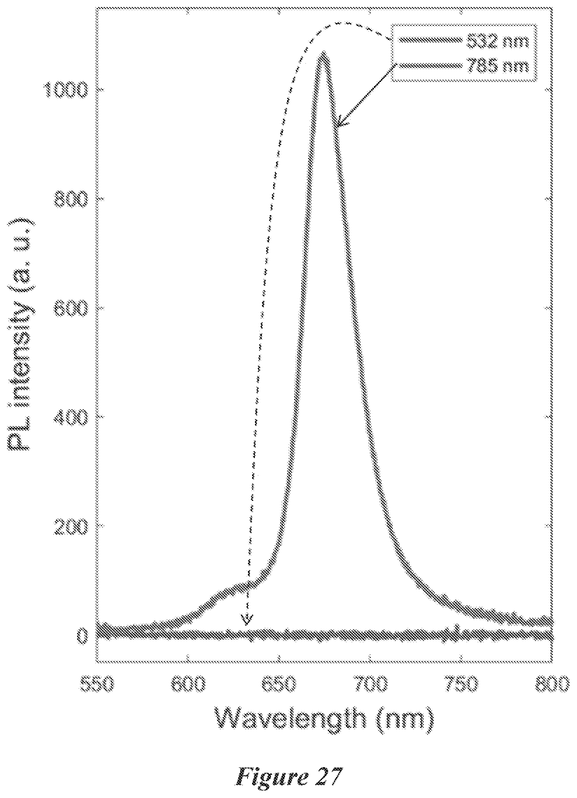

FIG. 23 shows an as-prepared 10-layer MoS₂ flake. Scanning the flake with a 532 nm laser beam (e.g., sufficient to optically pump electrons over the direct band gap of MoS₂) (˜135 μW/μm²) at ˜10 μm/s speed under 0.5 V potential removed all the layers within the scanned area (FIG. 24), which was verified by no photoluminescence signal collected at the scanned area (FIG. 27).

In the self-limiting optoelectronic thinning described herein, instead of optically pumping electrons over the direct band gap of MoS₂ (˜1.9 eV or ˜650 nm), a 785 nm laser beam was used to excite electrons over the indirect band gap (˜1.2-1.55 eV or ˜800 nm-1033 nm) via phonon-assisted light absorption (Grivickas, Solid Slate Commun., 1998, 108(8), 561-566; Bhargavi et al. J. Appl. Phys., 2015, 118(4), 044308). As an example, another thick MoS₂ flake (FIG. 25) was scanned with a 785 nm laser beam (˜5 mW/μm²) under a 0.5 V potential. To completely remove the top layers and leave only the atomic monolayer at the bottom, the flake was optically scanned twice at a speed of 5 μm/s. The resulting monolayer (FIG. 26) was verified by the strong photoluminescence signal collected from the scanned area (FIG. 27). The self-limiting arises from the fact that no electrons will be optically excited when the flake reaches monolayer as the photon energy of the laser beam (˜1.58 eV, 785 nm) is lower than the wider direct band gap of the monolayer MoS₂ (˜1.9 eV or ˜650 nm).

Conclusion. A self-limiting optoelectronic thinning technique to fabricate high-quality monolayers of transition metal dichalcogenides was demonstrated. The self-limiting capability enables the ability to obtain the atomic monolayers regardless of the original thickness of the transition metal dichalcogenide flakes and without an elaborate control of the experimental conditions. The self-limiting is enabled by optically pumping electrons only over the indirect band gap of the transition metal dichalcogenide flakes.

### Example 2

Introduction. Laser thinning is a promising top-down method to obtain high-quality thin or monolayer two-dimensional (2D) materials. Herein, an optoelectronic thinning method for fabricating transition metal dichalcogenide (TMDC) devices is presented. By selectively pumping electrons over the indirect band gap, self-limiting thinning of transition metal dichalcogenides to high quality monolayers was realized.

Methods and Procedures. FIG. 9 is a schematic illustration of the sample (cross-sectional view) and experimental set up for the self-limiting optoelectronic thinning.

To realize the optoelectronic thinning of the transition metal dichalcogenides, thick transition metal dichalcogenide flakes were firstly transferred onto clean glass substrates by mechanical exfoliation. Then electrodes with a typical in-plane Field Effect Transistor (FET) configuration were patterned by standard photolithography and lift-off processes, as illustrated in FIG. 9. During thinning, the transition metal dichalcogenide sample was dipped in deionized (DI) water and mounted on an inverted microscope. Electrical bias was applied between the transition metal dichalcogenide flake and the DI water. A low power 785 nm laser was then directed onto the transition metal dichalcogenide sample.

Data. To demonstrate the performance of the thinning method, the photoluminescence (PL) and Raman spectra of an MoS₂ flake were measured before and after thinning by the 785 nm laser, which confirmed monolayer results and self-limiting nature. Photoluminescence and Raman spectra of a mechanically exfoliated MoS₂ monolayer were also measured to show the higher quality of the MoS₂ monolayer obtained by thinning.

Optical micrographs of MoS₂ before and after thinning are shown in FIG. 10 and FIG. 11, respectively. The photoluminescence and Raman spectra of an exfoliated MoS₂ monolayer and a MoS₂ flake before (measured at the position indicated by the square in FIG. 10) and after (measured at the position indicated by the square in FIG. 11) thinning are shown in FIG. 12 and FIG. 13, respectively.

Optical micrographs of a MoS₂ flake before and after being thinned by a 532 nm laser beam are shown in FIG. 23 and FIG. 24, respectively. Optical micrographs of a MoS₂ flake before and after being thinned by a 785 nm laser beam are shown in FIG. 25 and FIG. 26, respectively. FIG. 27 shows the photoluminescence spectra measured from the MoS₂ flakes scanned by a 532 nm laser beam at the position indicated by the square in FIG. 24 and from the MoS₂ flake scanned by a 785 nm laser beam at the position indicated by the square in FIG. 26.

To explore the thinning mechanism, the photoluminescence spectra of monolayers and bilayers were measured under different bias. FIG. 19 shows the photoluminescence spectra of bilayer MoS₂ at different bias, e.g., from −0.5 V (bottom trace) to 0.5 V (top trace). The peak shifts indicated the trion-exciton transition was tuned by the applied bias (FIG. 19). Electrochemical reactions were proved by investigating the effect of the electrical current during thinning.

The removal of transition metal dichalcogenide materials is essentially an electrochemical degradation. The electrochemical reaction between transition metal dichalcogenides and water would be very slow. However, under excitation using light that pumps electrons from the valence band to the conduction band, the electrochemical reaction is promoted. Initially, the reaction happens in all layers. However, under negative gating, more electrons are distributed in the bottom layer (FIG. 22), which will induce lower degradation speed. As the NIR laser cannot pump electrons over the direct band gap, the thinning is self-limited to monolayer.

Results and Discussion. By selectively exciting electrons in the indirect band gap of bulk or few-layer MoS₂, thinning of the transition metal dichalcogenide is realized by optically promoted electrochemical degradation. Once the MoS₂ reached an atomic monolayer, Mo₂ underwent a transition from an indirect to a direct bandgap semiconductor and the laser beam could not excite the electrons over the wider direct band gap. Therefore, the electrochemical reaction stopped and the MoS₂ remained as an atomic monolayer.

Conclusions/Recommendations. A self-limiting optoelectronic thinning technique to fabricate high-quality monolayers of transition metal dichalcogenides was demonstrated. The self-limiting capability enables the ability to obtain atomic monolayers regardless of the original thickness of the transition metal dichalcogenide flakes and without an elaborate control of the experimental conditions. The self-limiting is enabled by optically pumping electrons only over the indirect band gap of the transition metal dichalcogenide flakes.

Methods to promote optical absorption from indirect band gap can be studied further,

### Example 3

### Self-Limiting Optoelectronic Thinning for Transition Metal Dichalcogenides Monolayers Fabrication

Transition metal dichalcogenides (TMDCs), with a direct band gap at single layer thicknesses, are widely studied in many fields, e.g., electrical, optical, electrochemical, biosensing, etc.. Monolayers of transition metal dichalcogenides are desired for a variety of applications because of their atomic thickness, direct band gap, and other outstanding properties.

As a result, high-quality and high-throughput production of transition metal dichalcogenide monolayers is a is an important topic in both research and application fields of transition metal dichalcogenides.

Since bottom-up chemical vapor-grown (CVD) monolayers usually have lower quality, top-down methods are employed to obtain high-quality monolayers. Many top-down thinning techniques, including plasma thinning, ion beam thinning, thermal thinning, laser thinning, and electrochemical thinning, have been developed to fabricate transition metal dichalcogenide monolayers from thick flakes. Compared to cleavage methods (mechanical, liquid, milling, etc.), thinning methods (including plasma thinning, ion beam thinning, thermal thinning, laser thinning, and electrochemical thinning) are believed to have higher throughput. However, all these methods require careful control of operating conditions to obtain monolayer thickness and cannot ensure uniform high quality. Further, flakes with different thicknesses will be thinned at the same speed under the same conditions. As a result, the thinner flakes will be totally removed. when the thicker flakes are thinned to monolayer, which limits the throughput of current methods.

Described herein is a self-limiting optoelectronic thinning (SOET) method for uniformly high-quality, high-throughput, and wafer-scale fabrication of transition metal dichalcogenide (TMDC) monolayers. The self-limiting optoelectronic thinning (SOET) method for high-efficiency thinning of flakes of transition metal dichalcogenides (TMDCs) into atomic monolayers described herein operates through coordinating the optical generation of optoelectronic and electrochemical degradation of transition metal dichalcogenides flakes in an aqueous environment. By pumping optoelectrons from the indirect band gap of thick transition metal dichalcogenide flakes, the developed method is a self-limiting technique for high-quality monolayer production with high throughput.

More specifically, by using a laser with a photon energy lower than the direct band gap but higher than the bilayer indirect band gap of operating transition metal dichalcogenides, the developed method will self-limit the final thickness to a single layer, which has not been realized by any other thinning method. Low-power (˜0.35 μW/μm² laser) and highly-efficient thinning of different transition metal dichalcogenides to uniform monolayers with high electrical and optical qualities is demonstrated in aqueous environment under vertical electrical field (0.5 V). The self-limiting optoelectronic thinning method can be applied to mass production of high-quality transition metal dichalcogenide monolayers, wafer-scale transition metal dichalcogenide monolayer synthesis, and in situ fabrication of monolayer transition metal dichalcogenide electronic and photonic devices.

Compared to current technologies, the technique described herein has advantages of being monolayer self-limiting, using low power, being low cost, producing high quality monolayers, having a high throughput, being highly efficient, enabling wafer-scale production, and using a simple optical setup.

The thinning methods described herein is conducted when the transition metal di chalcogenide flakes are set on a conducting substrate or connected to electrodes. However, many 2D material transfer methods can be used to subsequently transfer the fabricated monolayers to other substrates.

The self-limiting optoelectronic thinning methods described herein can be used to produce transition metal dichalcogenide monolayers for a variety of applications, such as for flexible electronic and photonic devices.

### Example 4

### Self Limiting Opto-Electroc Thinning of Transition Metal Dichalcogenides

Abstract. Two-dimensional monolayer and few-layer transition metal dichalcogenides (TMDs) are promising for advanced electronic and photonic applications due to their extraordinary optoelectronic and mechanical properties. However, it has remained challenging to produce high-quality transition metal dichalcogenide thin films with controlled thickness and desired micropatterns, which are essential for their practical implementation in functional devices. In this work, a self-limiting opto-electrochemical thinning (sOET) technique is developed for on-demand thinning and patterning of transition metal dichalcogenide flakes at high efficiency. Benefiting from optically enhanced electrochemical reactions, sOET features a low operational optical power density of down to 70 μW μm⁻² to avoid photodamage and thermal damage to the thinned transition metal dichalcogenide flakes. Through selective optical excitation with different laser wavelengths based on the thickness-dependent bandgap of transition metal dichalcogenide materials, sOET enables precise control over the final thickness of transition metal dichalcogenide flakes. With the capability of thickness control and site-specific patterning, sOET offers an effective route to fabricating high-quality transition metal dichalcogenide materials for a broad range of applications in nanoelectronics, nanomechanics, and nanophotonics.

Main text. Since the discovery of graphene, atomically thin two-dimensional (2D) materials have attracted great interest owing to their new and extraordinary physical properties beyond their bulk parent. Unlike zero-bandgap graphene (Novoselov K S et al. Nature 2012, 490, 192), monolayers of transition metal dichalcogenides (TMDs), such as MoS₂, WS₂, and WSe₂, exhibit a direct bandgap ranging from visible to near-infrared frequency (Manzeli S et al. Nat. Rev. Mater. 2017, 2, 17033). Besides monolayers, few-layer transition metal dichalcogenides also present unique and intriguing phenomena, such as interlayer excitons (Peimyoo N et al. Nat. Nanotechnol. 2021, 16, 4; Leisgang N et al. Nat. Nanotechnol. 2020, 15, 901), piezoelectricity (Lee J H et al. Adv. Mater. 2017, 29, 1), and superconductivity (Liu C X. Rev. Lett. 2017, 118, 1; Kanasugi S et al. Phys. Rev. B 2020, 102, 94507). Additionally, 2D transition metal dichalcogenides possess other excellent features, including large surface-to-volume ratio, strong spin-orbit coupling, and spin-valley locking, making them promising for many applications in photodetection (He Y M et al. Nat. Nanotechnol. 2015, 10, 497; Chen J et al. ACS Appl. Mater. Interfaces 2019, 11 , 43330; Chen Y et al. Nat. Electron. 2021, 4, 357), valleytronics (Schaibley J R et al. Nat. Rev. Mater. 2016, 1, 16055; Li L et al. Nat. Nanotechnol. 2020, 15, 743), sensing (Hu. Yet al. Mater. Chem. Front. 2017, 1, 24; Ping T et al. Adv. Funct. Mater. 2017, 27, 1605817), biomedical imaging (Zhou X et al. Front. Bioeng. Biotechnol. 2020, 8, 236; Zhu C et al. 2D Mater. 2015, 2, 032004), and drug delivery (Li B L et al. ACS Appl. Mater. Interfaces 2017, 9, 15286; Wang S et al, Adv. Mater. 2015, 27, 7117; Yadav V et al. Small 2019, 15, 803706).

To fully unleash the potential of transition metal dichalcogenide materials, it is essential to fabricate high-quality transition metal dichalcogenide flakes with controlled thickness and microstructures. Mechanical exfoliation is widely exploited to prepare high-quality monolayer and few-layer transition metal dichalcogenide flakes. However, mechanically exfoliated transition metal dichalcogenide flakes are usually small in lateral size and have poor thickness control (Huang Y et al. ACS Nano 2015, 9, 10612; Huang Y et al. Nat. Commun. 2020, 11, 2453). In contrast, the liquid-phase exfoliation method is more scalable, but it may result in poor quality and unwanted contaminations. Alternatively, synthetic approaches, such as chemical vapor deposition (CVD) and molecular beam epitaxy (MBE), can produce transition metal dichalcogenide monolayers on a large scale (Lee Y R et al, Adv. Mater. 2012, 24, 2320; Roy A et al. ACS Appl. Mater. Interfaces 2016, 8, 7396). However, both CVD and MBE require complex and expensive equipment, and the electrical properties of the chemically grown transition metal dichalcogenides are typically inferior to the exfoliated ones.

Recently, laser thinning has emerged as a promising top-down approach for low-cost and high-throughput fabrication of transition metal dichalcogenides layers with site-specific control (Castellanos-Gomez A et al. Nano Lett. 2012, 12, 3187). For instance, on-demand thinning of MoS₂ with layer-by-layer precision was demonstrated with a high-fluence laser beam (30-80 mW m⁻²) to burn the top layers (Hu L et al. Sci. Rep. 2017, 7, 15538). Yet, this high optical power leads to a notable temperature increase, which could induce the phase transition of transition metal dichalcogenides and affect the quality of the thinned films (Cho S et al. Science 2015, 349, 625). In another approach, Nagareddy demonstrated on-demand thinning of MoTe₂ flakes by a much lower laser fluence (0.3-4 mW m⁻²) with the assistance of adsorbed water vapor on the flake surface (Nagareddy V K et al. Adv. Funct. Mater. 2018, 28, 1804434). However, this thinning process relies on the weak thermal and chemical stability of MoTe₂ (Zhu H et al. ACS Nano 2017, 11, 11005), which is not applicable to other transition metal dichalcogenide materials with strong interatomic bonding, such as MoS₂ and WS₂.

Alternatively, optoelectronic thinning has been proposed to realize the thinning of transition metal dichalcogenides in aqueous solutions through optically-controlled electrochemical etching. In comparison to direct laser thinning via thermal sublimation, the electrochemical approaches typically require a much lower temperature, which enables the removal of top layers without sacrificing the properties of the bottom layer (Rho Y et al. ACS Appl. Mater Interlaces 2019, 11, 39385). Optoelectronic thinning of bulk MoS₂ was demonstrated to prepare monolayers on gold substrates (Sunamura K et al. J. Mater. Chem. C 2016, 4, 3268; Wit S S et al. 2D Mater, 2019, 6, 045052). However, the reliable production of monolayer MoS₂ was challenging due to the reliance on the electrochemical reaction time, which would demand high-resolution in situ monitoring of the number of the layers and an effective method for terminating the reaction once the monolayer is achieved. In addition, the capability to precisely control the final thickness of the thinned transition metal dichalcogenide flakes in a layer-by-layer fashion has remained elusive. Such a precise control is critical to applications that require an exact number of layers (i.e., one, two or more layers).

Herein, a self-limiting opto-electrochemical thinning (sOET) technique for on-demand thinning and patterning of transition metal dichalcogenides is reported. The optically activated electrochemical etching automatically stops once transition metal dichalcogenides flakes are thinned to the targeted thicknesses (i.e., one, two or more layers), which is accomplished by using a specific laser wavelength depending on the bandgap energy of the targeted number of layers. No sophisticated engineering of thinning conditions is needed. Further, the high-throughput thinning of large transition metal dichalcogenide flakes down to the monolayer with equivalent quality to pristine exfoliated monolayers is demonstrated herein. Together with the low-power operation, general applicability, and tunable thinning rates, sOET provides new possibilities in the reliable fabrication of high-quality transition metal dichalcogenides for their applications in advanced electronic and photonic devices.

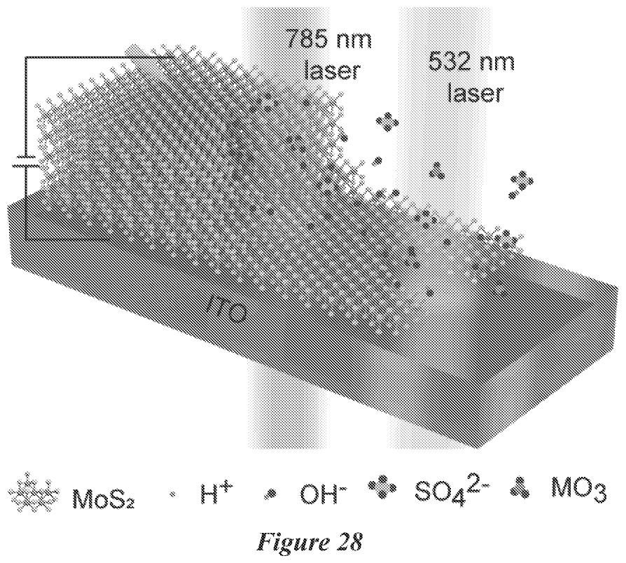

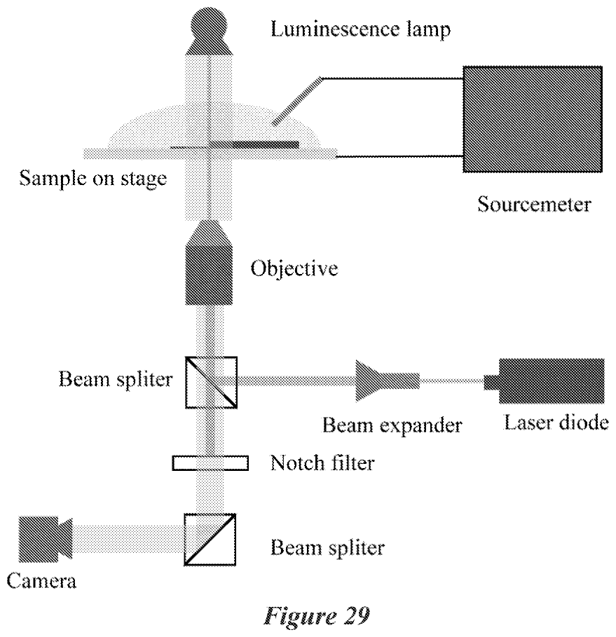

The general concept of sOET is shown in FIG. 28. Briefly, a thick transition metal dichalcogenide flake, such as MoS₂, is transferred onto an indium tin oxide (ITO) substrate. Meanwhile, the flake is immersed in deionized (DI) water and biased with a suspending electrode in the liquid (see FIG. 29 for experimental setup). To enable light-directed electrochemical thinning of MoS₂, a laser beam is directed onto the flake to excite electrons from the valence band to the conduction band and generate electron-hole pairs. Under an electrical bias, electrons are conducted to the suspending electrode, leaving excessive holes on the flake. At the edge or defect of the flake, MoS₂ can be oxidized in the presence of holes and hydroxide ions via electrochemical reactions (Wu S S et al. 2D Mater. 2019, 6, 045052; Sakamaki K. J. Vac. Sci. Technol. B Microelectron. Nanom. Struct. 1991, 9, 944):

MoS₂+OH⁻+h⁺→MoS₃+SO₄²⁻+H₂O (1)

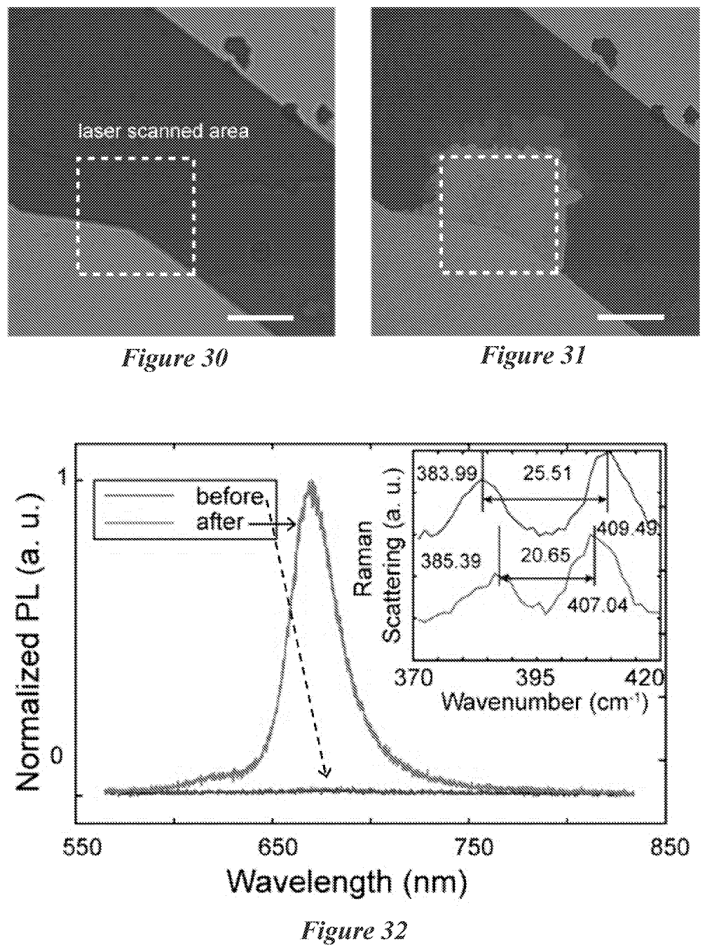

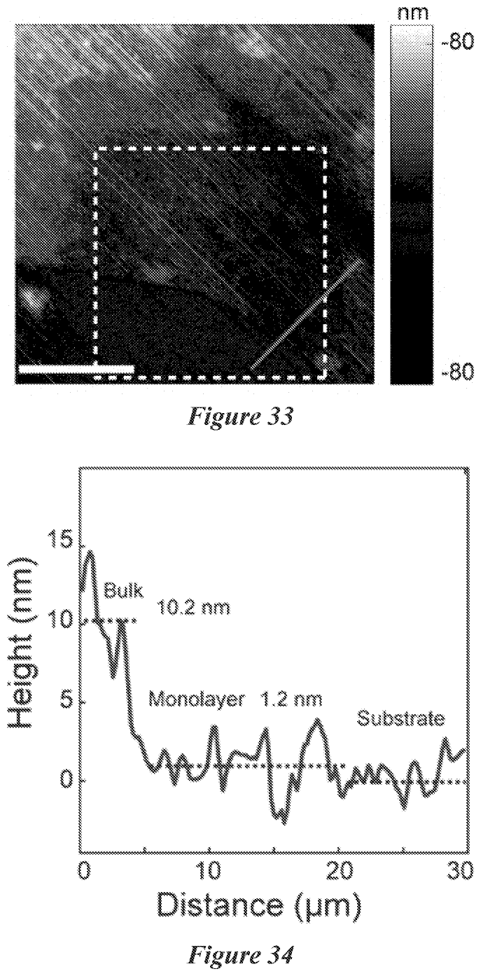

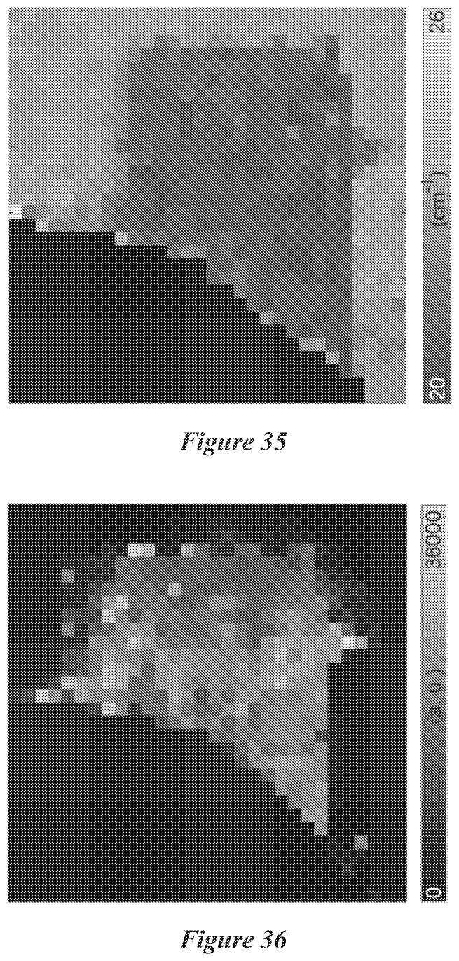

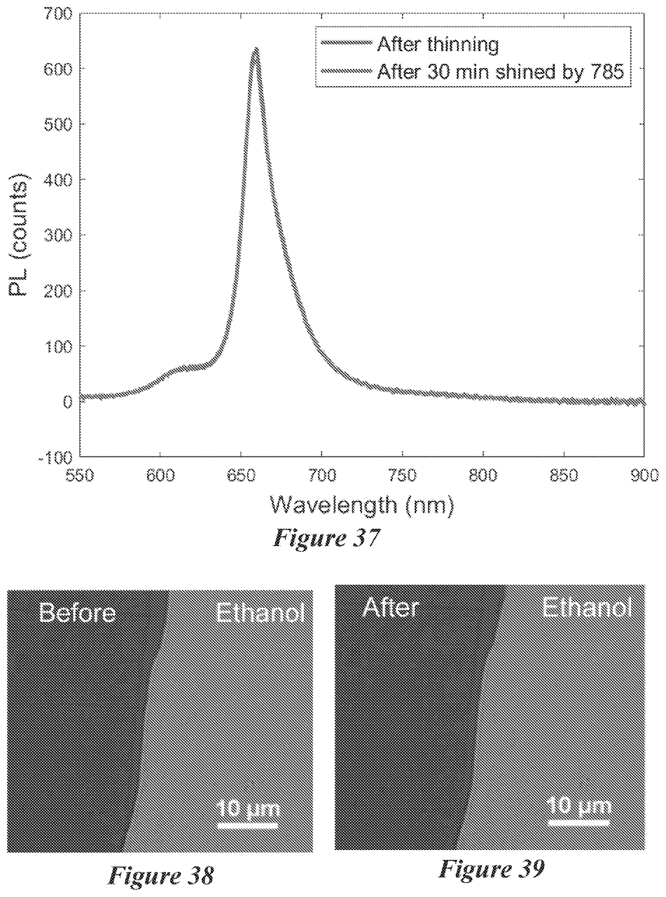

As a proof-of-concept demonstration, the laser thinning of a pristine thick MoS₂ flake prepared by mechanical exfoliation is shown (FIG. 30). After being illuminated by a 785 nm laser with a power density of 69.6 μW μm⁻² under 0.2 V bias, the scanned area was successfully thinned (FIG. 31). Atomic force microscopy (AFM) measurements reveal that the flake was thinned from ˜10.2 nm to ˜1.2 nm, which indicates a monolayer (FIG. 33, FIG. 34). After laser scanning, the as-thinned region showed dramatically enhanced photoluminescence (PL) at 673 nm (FIG. 32), confirming its monolayer feature. In addition, the difference between E¹_{2g} and A_{1g} Raman modes was reduced from ˜25.5 cm⁻¹ to ˜20.6 cm⁻¹ (Inset in FIG. 32, also see FIG. 35 and FIG. 36 for spatial mapping of Raman scattering and photoluminescence signals), which agrees well with the Raman spectra of monolayer MoS₂ (Chakraborty B et al. Phys. Rev. B Condon. Matter Mater. Phys. 2012, 85, 2; Panasci S E et al. ACS Appl. Mater. Interfaces 2021, 13, 31248). This opto-electrochemical thinning will not affect the quality of the thinned monolayer, which is highly stable and shows no degradation in photoluminescence intensity after laser excitation for 30 min (FIG. 37).

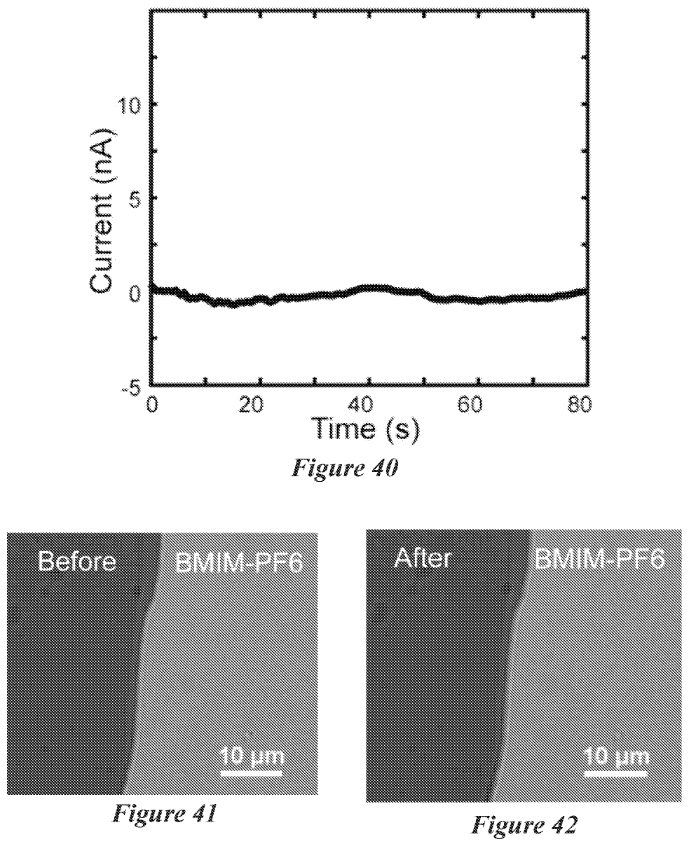

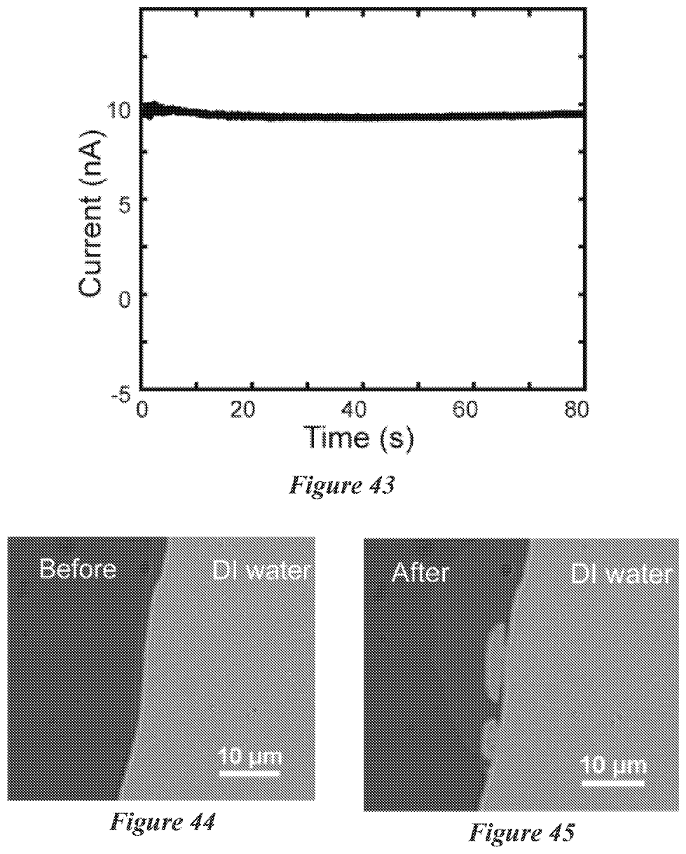

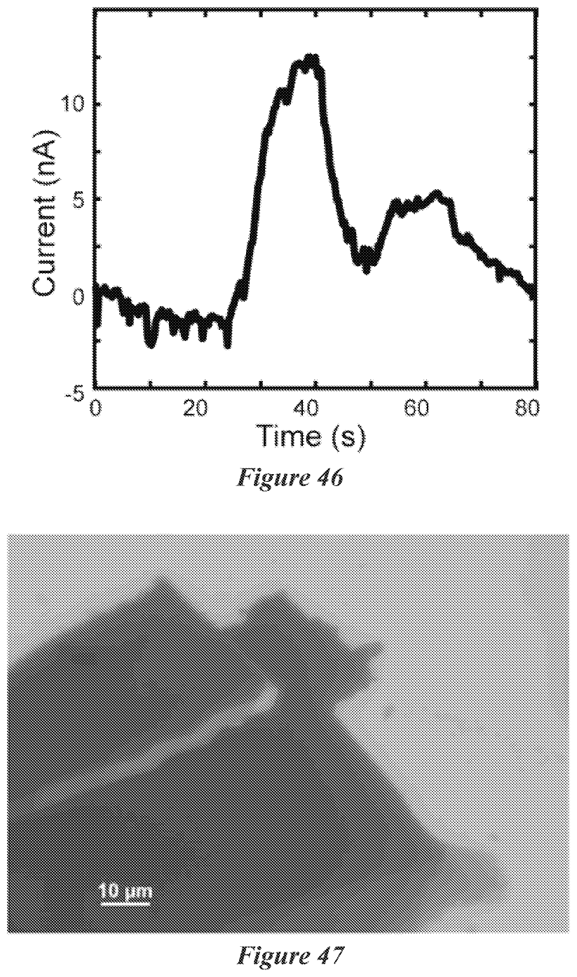

To fully understand the underlying mechanism of sOET, thinning experiments were conducted in different solutions and the current change during the thinning process was monitored. In a non-conductive liquid (e.g., ethanol), the electrochemical reactions were inhibited (FIG. 38, FIG. 39) since the optically activated electrons could not be extracted from MoS₂ to the electrode (the gate current is zero, FIG. 40). In a conductive ion liquid ((1-butyl-3-methylimidazolium hexafluorophosphate, BMIM-PF6), a stable gate current of ˜10 nA was observed (FIG. 43). However, the electrochemical thinning still did not happen (FIG. 41, FIG. 42), which indicates the essential role of water (hydroxide ions) in the reaction. In contrast, with the existence of hydroxide ions, the MoS₂ flake was rapidly thinned in DI water (FIG. 44, FIG. 45), which is weakly conductive to support the electron transfer. An increase in gate current was observed synchronously during the thinning process (FIG. 46), which indicates electron transfer during the thinning and proves that sOET is based on electrochemical reactions.

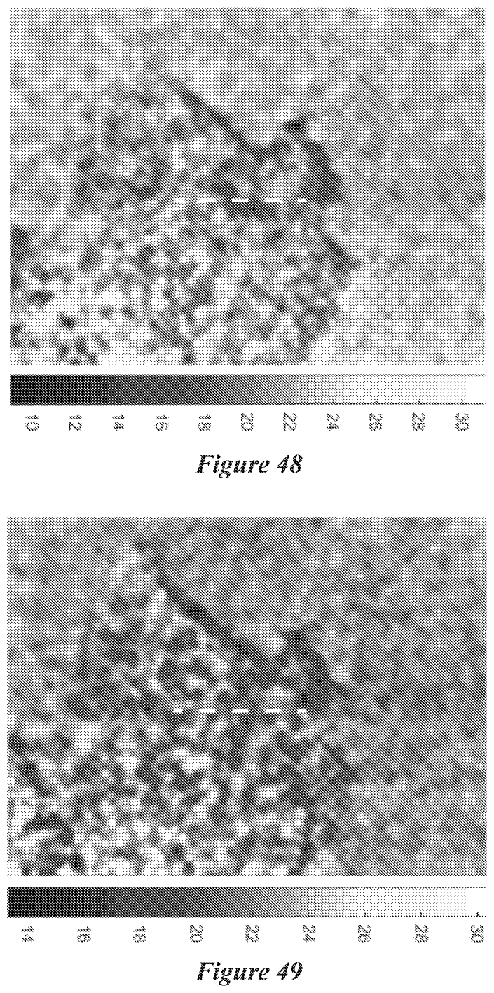

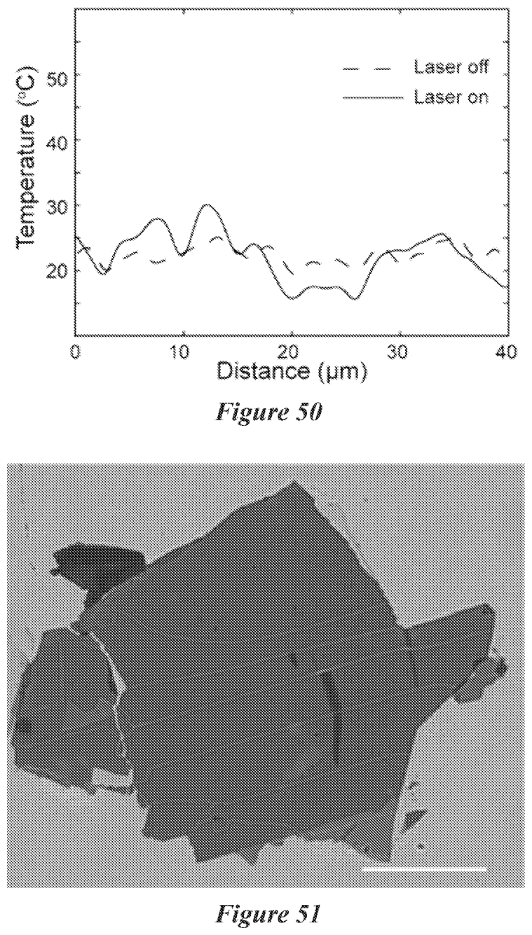

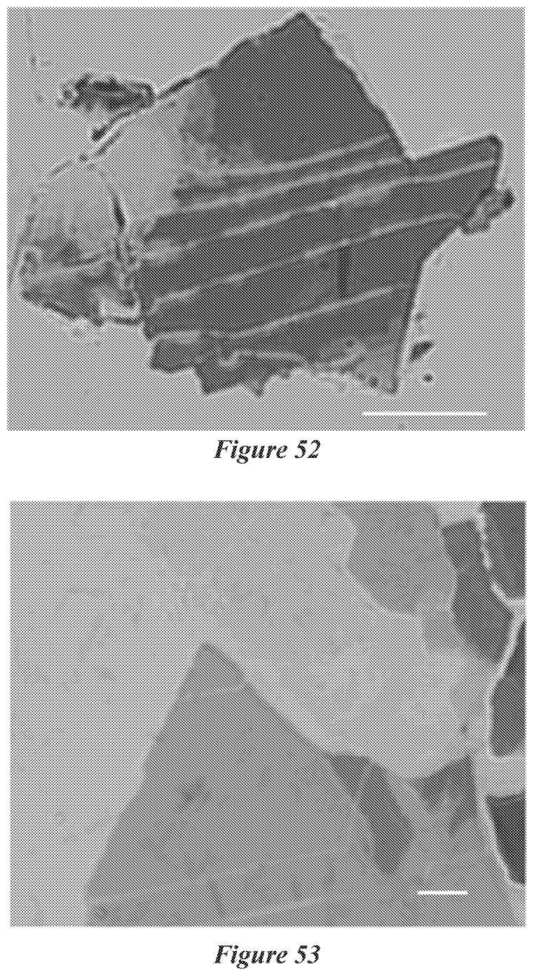

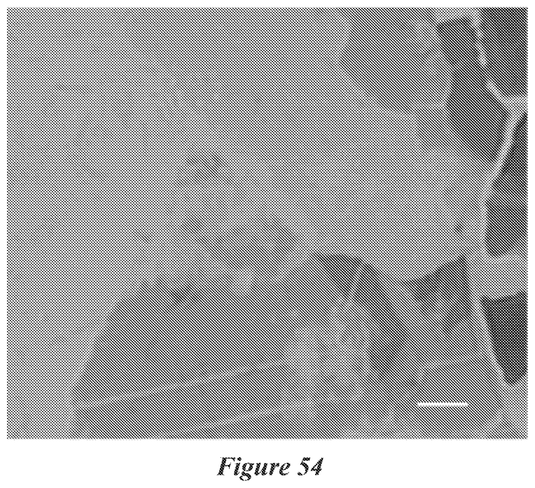

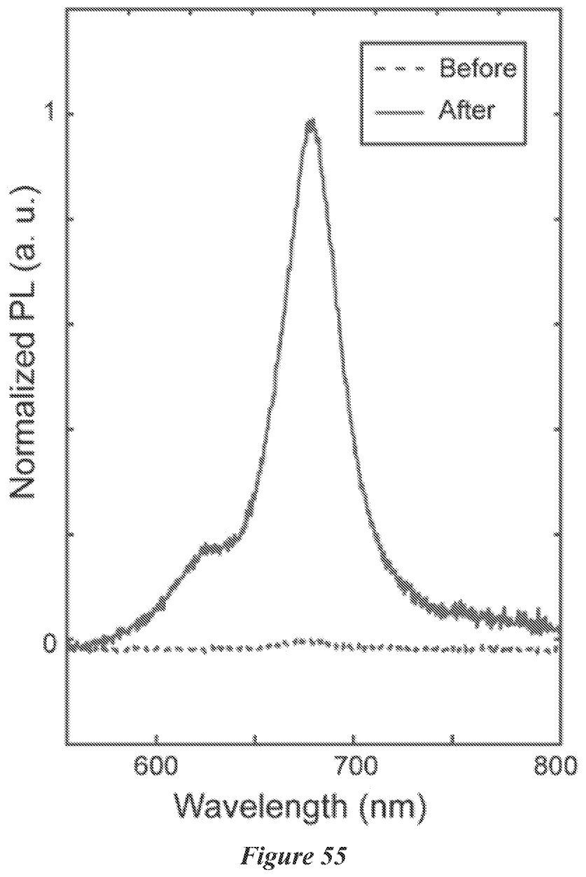

It should be noted that sOET preferably starts from the edge of transition metal dichalcogenide flakes with a high density of defects, while it cannot be initiated at the center region with limited detects. Defects at the flake edge could provide a large quantity of dangling bonds, which are important active sites for electrochemical reactions (Sivaram S V et al. ACS Appl. Mater. Interfaces 2019, 11, 16147). However, the laser thinning could still be initiated from the center of the flake via Ar plasma treatment to increase the defect density. In addition, the photothermal effect in sOET process is negligible. The temperature of a MoS₂ flake in DI water under irradiation of a 785 nm laser was experimentally measured using a phase camera (see Experimental Section for more details). The temperature increase was not obvious under a typical operational power density (0.102 mW μm⁻²) (FIG. 47-FIG. 50). Successful thinning of transition metal dichalcogenide flakes was also demonstrated on other conductive substrates, such as gold thin film and monolayer graphene, with the same configuration (FIG. 51-FIG. 55). Interestingly, sOET could take place with no electrical bias on gold film or graphene, which results from the spontaneous electron transfer from MoS₂ to gold film or graphene (Lorchat E et al. Nat. Nanotechnol. 2020, 15, 283; Bhanu U et al. Sci. Rep. 2014, 4, 5575), similar to applying a bias voltage.

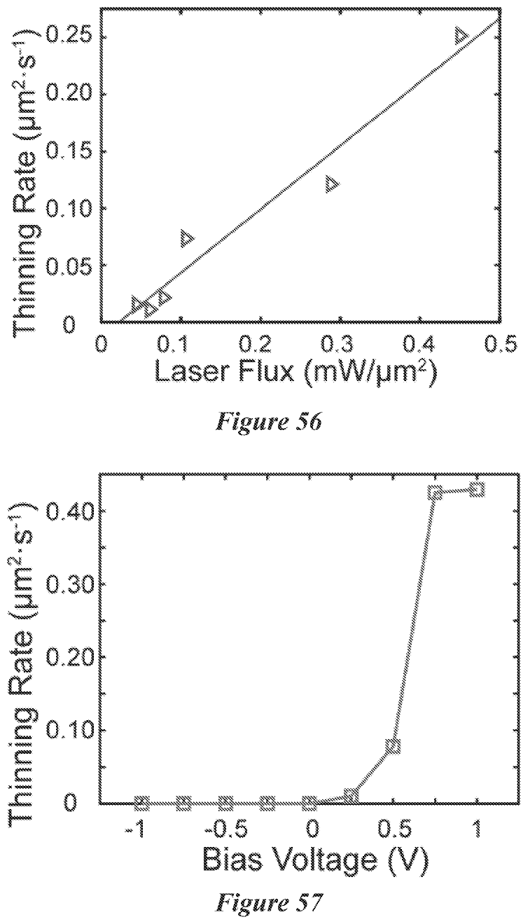

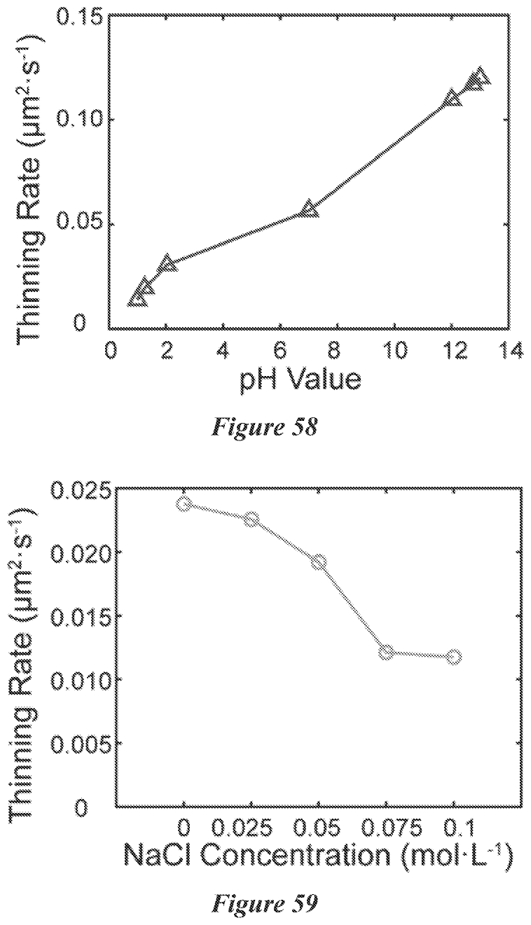

Based on the understanding of the thinning mechanisms, highly tunable thinning rate of sOET was achieved. First, since sOET is enabled by the optically activated electrochemical reactions, the thinning rate can be controlled by the laser power and the bias voltage. The thinning rate increased linearly along with the laser power (FIG. 56) as the optically excited electron density is proportional to the excitation power. Since sOET relies on the directional electron transfer, no obvious thinning was observed under a negative bias. When the bias increased from zero to positive, the thinning rate rose sharply and saturated at a bias of ˜0.75 V (FIG. 57). The increase of the positive bias voltage can lead to more p-doping in transition metal dichalcogenide flakes and a faster electron transfer rate, which enhances the thinning rate. The saturation was ascribed to the limited optical pumping rate under a fixed laser power. In addition to the optical power and bias, the pH value and ionic concentration of solutions can remarkably affect the opto-electrochemical thinning. FIG. 58 shows the thinning rate in sodium hydroxide/sodium chloride (NOH/NaCl) solutions with the same total ionic concentrations but different pH values (see Experimental Section for details). Along with the increasing pH value, the concentration of hydroxide ions also increased, which provided more reactants in Reaction Equation 1 and enhanced the thinning rate. In contrast, a higher concentration of other ions, such as NaCl, could affect the thinning rate in a negative way (FIG. 59). This result is probably because non-reactive chloride ions can compete with reactive hydroxide ions to be attracted to the vicinity of the reactive sites.

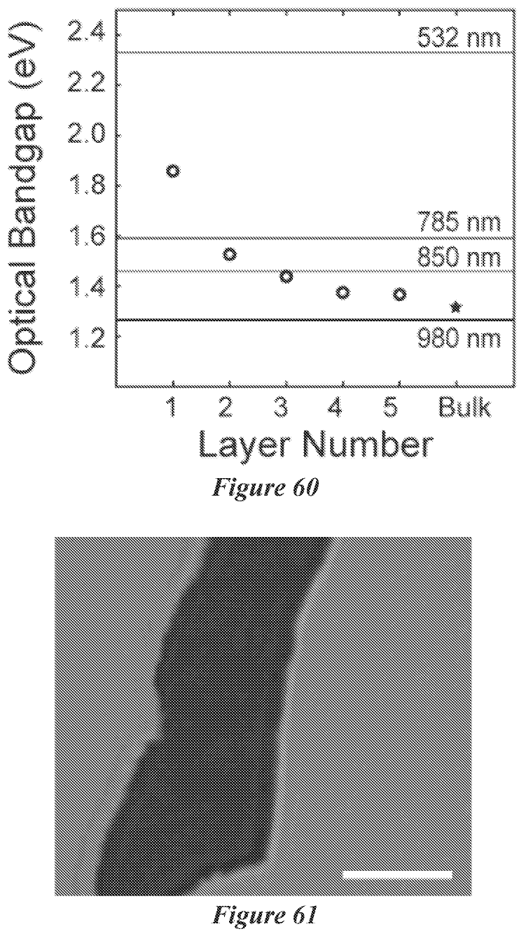

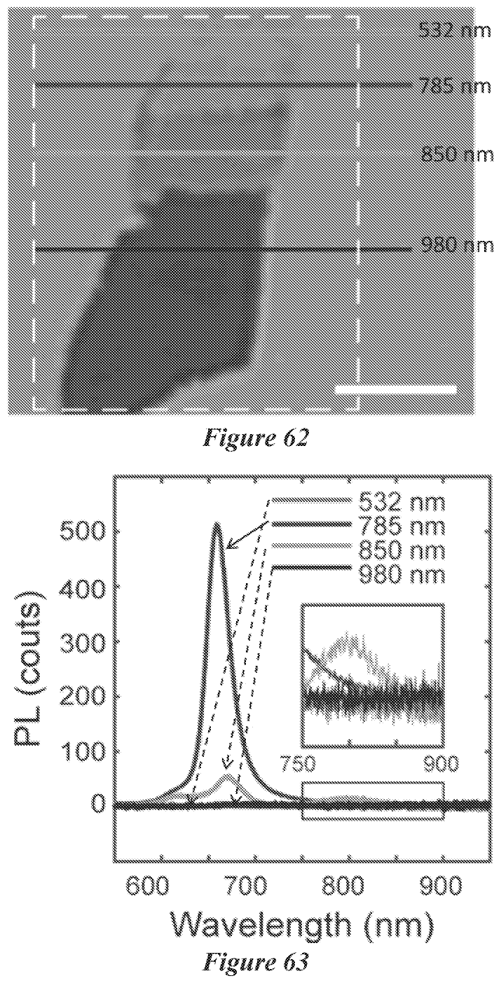

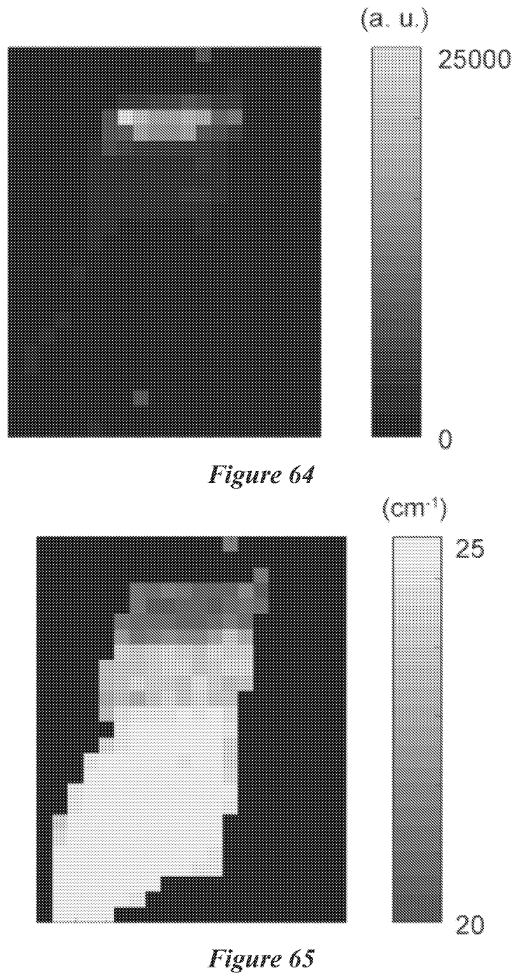

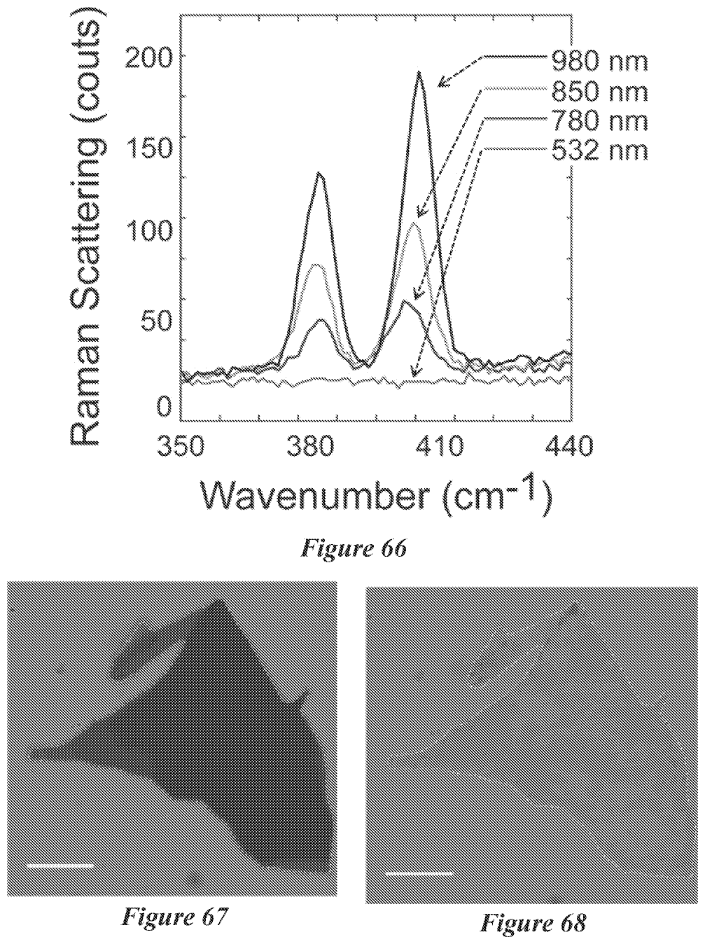

Unlike the previously reported, optoelectronic thinning methods that preferably thin bulk or few-layer transition metal dichalcogenides to monolayers, sOET allows on-demand tinning of transition metal dichalcogenide flakes to the desired thickness. By selecting the laser photon energy according to the layer-dependent bandgaps, sOET can realize the thinning of transition metal dichalcogenide flakes into different thicknesses. Taking MoS₂ as an example (FIG. 60), the thinning of a MoS₂ flake via sOET is shown using 532 nm, 785 nm, 850 nm, and 980 nm lasers. After thinning, the different thicknesses could be easily distinguished from the optical contrasts (FIG. 61, FIG. 62), photoluminescence signals (FIG. 63, FIG. 64), and Raman spectra (FIG. 65). A 980 nm laser (1.26 eV) cannot thin the MoS₂ flake since the photon energy is lower than the bandgap of bulk MoS₂ (1.29 eV), In contrast, a 532 nm laser (2.33 eV) with the photon energy higher than the bandgap of monolayer MoS₂ (1.84 eV) can remove all the flake, as no photoluminescence or Raman signals were detected from the scanned area. Similarly, the use of a 785 nm or an 850 nm laser can lead to the thinning of a thick MoS₂ flake to a monolayer or bilayer. The photoluminescence and Raman measurements also showed the strongest photoluminescence intensity (FIG. 63) and smallest distance between two Raman modes (FIG. 66), which confirms the monolayer MoS₂ after thinning by the 785 nm laser. The bilayer MoS₂ thinned by an 850 nm laser was also proved by the indirect emission at 805 nm (Inset in FIG. 63).

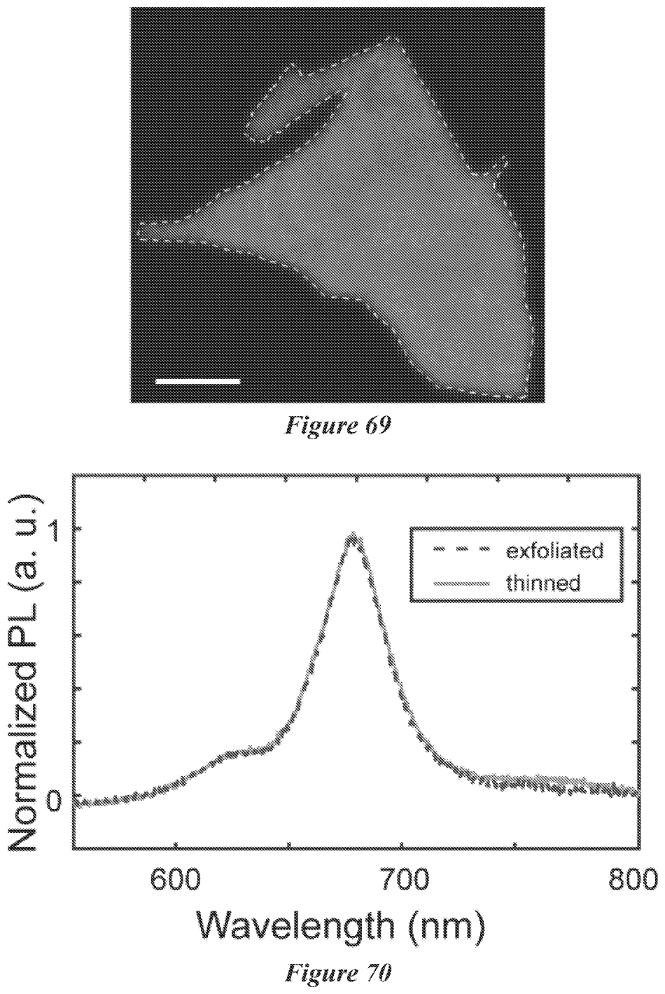

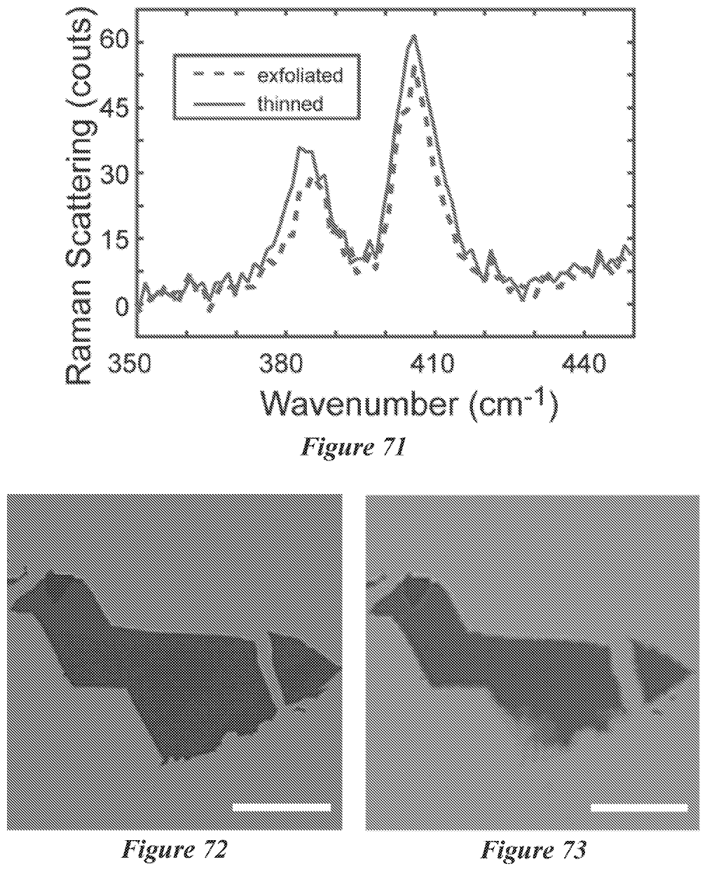

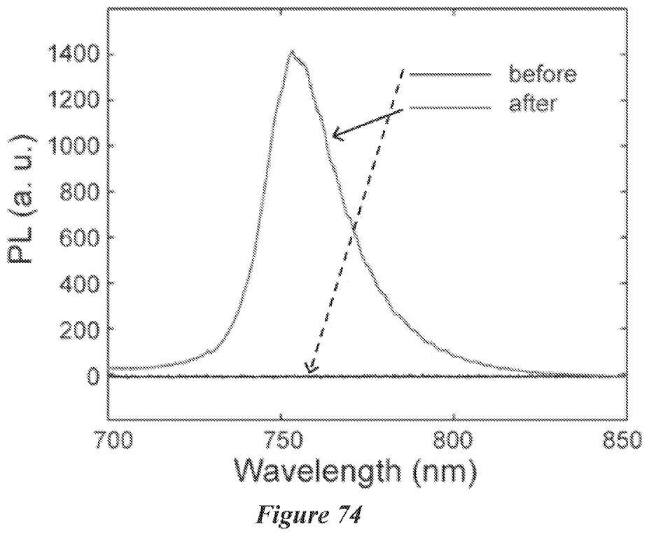

Last, the efficient thinning of large transition metal dichalcogenide flakes into monolayer was demonstrated to show the potential of sOET in the mass production of high-quality monolayer transition metal dichalcogenides. A MoS₂ flake with the dimension of ˜100 μm×100 urn was successfully thinned into a monolayer by a 785 nm laser in less than 5 min (FIG. 67, FIG. 68). The resultant monolayer showed strong and uniform photoluminescence under the excitation of a 532 nm laser (FIG. 69). The photoluminescence and Raman measurements showed comparable data with the mechanically exfoliated monolayer MoS₂ (FIG. 70, FIG. 71), confirming the high quality of the thinned monolayers. It should be noted that the current thinning throughput is limited by the laser beam size and line-by-line scanning, which can be greatly improved with uniform large-area luminescence. In addition to MoS₂, sOET also works for other transition metal dichalcogenide materials. For instance, the thinning of WSe₂ flakes into a monolayer was demonstrated by a 785 nm laser (FIG. 72-FIG. 74), which proves the general applicability of sOET.

In summary, sOET was developed for on-demand and high-throughput thinning of transition metal dichalcogenides with excellent material quality. sOET is enabled by optically activated electrochemical reactions, where the thinning rate can be actively controlled by optical power, electrical bias, pH value, and ionic concentration. By rationally selecting laser photon energies based on the layer-dependent bandgaps of transition metal dichalcogenide materials, the precise control of the final thickness of the thinned transition metal dichalcogenide flakes was realized. As a general technique, sOET is applicable to a wide range of transition metal dichalcogenide materials, which presents great potential for the mass production of high-quality transition metal dichalcogenide monolayers and few layers. With the low operational power, thickness-selective thinning, and site-specific patterning capabilities, sOET can provide new possibilities in the nanofabrication of transition metal dichalcogenide materials to advance their applications in many fields, including nanoelectronics and nanophotonics.

### Experimental Section

Sample preparation: ITO coverslips (SPI supplies) were cleaned by ultrasonication in acetone and isopropanol for 10 min, respectively, then rinsed by DI water and dried by nitrogen flow. Transition metal dichalcogenides flakes were exfoliated from bulk materials to polydimethylsiloxane (PDMS) with scotch tape, Then the PDMS with transition metal dichalcogenide flakes was brought into contact with cleaned ITO coverslips and pressed for 10 min. Finally, the PDMS was removed by heating it up to 130° C., and the transition metal dichalcogenide flakes were successfully transferred to the ITO coverslip.

sOET procedure: The transition metal dichalcogenide flakes on ITO coverslips were mounted on an inverted microscope (Ti-E, Nikon). A solution (ethanol, DI water, NaCl solutions, or NaOH solutions) of ˜200 μL volume was dropped on ITO to cover the transition metal dichalcogenide flakes. Electrical bias was applied by a Keithley sourcemeter (Keithley 2612B) with one electrode connecting the ITO and the other suspended in the solution. Lasers were directed to the transition metal dichalcogenides from the bottom by a 40× objective (NA 0.75). 532 nm (Ventus 532, Laser Quantum) and 785 nm (TEC 510, Sather Lasertechnik) continuous-wave lasers were used. In addition, the 850 nm and 980 nm lasers were filtered by bandpass filters (Thorlabs) from a supercontinuum laser (SuperK FIANIUM-15, NKT 30 photonics). During scanning, the stage was controlled by LabView programs, For pH values tuned thinning rate experiments, NaCl/NaOH mixed solutions were used, the total sodium concentration was controlled to be 0.1 M. For the WSe₂ thinning experiments, 0.1 M NaOH solution was used. For other thinning experiments, DI water was used.

Optical characterization: Photoluminescence and Raman spectra were measured by a spectrometer (Andor) with an EMCCD (Andor). The signals were excited by the 532 nm laser and collected from a 100× objective (NA 0.6, Nikon). The laser power was set to be 250 μW for photoluminescence measurements and 755 μW for Raman measurements.

ATM measurement: AFM measurement was carried out on a Park NX10 AFM (Park). The scanned area was set to be 60 nm×60 nm. The scanning rate was 128 Hz. After measurement, the data was processed by Park XEI AFM data analysis software.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A method of thinning a transition metal dichalcogenide material, the method comprising:
illuminating a first location of the transition metal dichalcogenide material with electromagnetic radiation while applying a positive potential between the transition metal dichalcogenide material and a gate electrode;
wherein the transition metal dichalcogenide material has a thickness at the first location that is greater than a monolayer;
wherein:
when the thickness of the transition metal dichalcogenide material at a location is a monolayer, then the transition metal dichalcogenide material has a direct band gap; and
when the thickness of the transition metal dichalcogenide material at the location is greater than a monolayer, then the transition metal dichalcogenide material has an indirect bandgap;
wherein the indirect band gap has an energy that is the difference between a valence band and a conduction band;
wherein the direct band gap has an energy that is the difference between a valence band and a conduction band;
wherein the indirect band gap is lower in energy than the direct band gap;
wherein the electromagnetic radiation has an energy that is less than the energy of the direct band gap and greater than or equal to the energy of the indirect band gap;
wherein the transition metal dichalcogenide material is disposed on a surface of a substrate;
wherein a source electrode is disposed on the surface of the substrate;
wherein the source electrode is in electrical contact with the transition metal dichalcogenide material;
wherein the gate electrode is not in physical contact with the transition metal dichalcogenide material;
wherein an aqueous solution is disposed on the surface of the substrate, such that the transition metal dichalcogenide material and the source electrode, are both submerged in the aqueous solution and the gate electrode is in electrochemical contact with the aqueous solution; and
wherein the source electrode and gate electrode are connected to a power source configured to apply a positive potential between the source electrode and the gate electrode, thereby applying the positive potential between the transition metal dichalcogenide material and the gate electrode;
thereby:
promoting electrons from the valence band to the conduction band of the indirect band gap and decreasing the thickness of the transition metal dichalcogenide at the first location via electrochemical degradation, thereby thinning the transition metal dichalcogenide at the first location;
wherein the method is self-limiting as the electrochemical degradation ceases when the thickness of the transition metal dichalcogenide at the first location is decreased to a monolayer, because the energy of the electromagnetic energy is insufficient to promote electrons from the valence band to the conduction band of the direct band gap.

2. The method of claim 1, wherein the transition metal dichalcogenide comprises MoS₂, WS₂, MoSe₂, WSe₂, MoTe₂, WTe₂, or a combination thereof.

3. (canceled)

4. The method of claim 1, wherein the electromagnetic radiation has a power density of from 0.1 mW/μm² to 30 mW/μm².

5. (canceled)

6. The method of claim 1, wherein the electromagnetic radiation is provided by a laser.

7. (canceled)

8. (canceled)

9. The method of claim 1, wherein the electromagnetic radiation is provided by an electromagnetic radiation source and the electromagnetic radiation source is configured to:
illuminate a mirror and the mirror is configured to reflect the electromagnetic radiation from the electromagnetic radiation source to illuminate the first location;
illuminate a plurality of mirrors and the plurality of mirrors are configured to reflect the electromagnetic radiation from the electromagnetic radiation source to illuminate the first location; or
illuminate a digital micromirror device comprising a plurality of mirrors and the plurality of mirrors are configured to reflect the electromagnetic radiation from the electromagnetic radiation source to illuminate the first location.

10. (canceled)

11. (canceled)

12. The method of claim 1, wherein the substrate is substantially transparent to the electromagnetic radiation; wherein the substrate is a dielectric substrate; or a combination thereof.

13-26. (canceled)

27. The method of claim 1, wherein the first location is illuminated for an amount of time of from 1 second to 10 minutes.

28. (canceled)

29. The method of claim 1, further comprising illuminating a second location of the transition metal dichalcogenide material, wherein the transition metal dichalcogenide material has a thickness at the second location that is greater than a monolayer, thereby:
promoting electrons from the valence band to the conduction band of the indirect band gap and decreasing the thickness of the transition metal dichalcogenide at the second location via electrochemical degradation, thereby thinning the transition metal dichalcogenide at the second location;
wherein the method is self-limiting as the electrochemical degradation ceases when the thickness of the transition metal dichalcogenide at the second location is decreased to a monolayer, because the energy of the electromagnetic energy is insufficient to promote electrons from the valence band to the conduction band of the direct band gap.

30. The method of claim 29, wherein the substrate is translocated to illuminate the second location; wherein the electromagnetic radiation is provided by a light source, and the light source is translocated to illuminate the second location;
wherein the electromagnetic radiation is provided by an electromagnetic radiation source, the electromagnetic radiation source being configured to illuminate a mirror and the mirror is configured to reflect the electromagnetic radiation from the electromagnetic radiation source to illuminate the transition metal dichalcogenide material, and the mirror is translocated to illuminate the second location; or a combination thereof.

31. (canceled)

32. (canceled)

33. The method of claim 29, wherein the second location is illuminated for an amount of time of from 1 second to 10 minutes.

34. (canceled)

35. The method of claim 1, wherein the method comprises:
sequentially illuminating a plurality of locations by scanning the electromagnetic radiation across the transition metal dichalcogenide material;
wherein the transition metal dichalcogenide material has a thickness at least a portion of the plurality of locations that is greater than a monolayer, said portion of the plurality of locations having a thickness that is greater than a monolayer being a first portion of the plurality of locations;
thereby decreasing the thickness of the transition metal dichalcogenide at the first portion of the plurality of locations.

36. (canceled)

37. The method of claim 35, wherein the substrate is translocated to sequentially illuminate the plurality of locations; wherein the electromagnetic radiation is provided by a light source, and the light source is translocated to sequentially illuminate the plurality of locations; wherein the electromagnetic radiation is provided by an electromagnetic radiation source, the electromagnetic radiation source being configured to illuminate a mirror and the mirror is configured to reflect the electromagnetic radiation from the electromagnetic radiation source to illuminate the transition metal dichalcogenide material, and the mirror is translocated to illuminate the plurality of locations; or a combination thereof.

38. The method of claim 35, wherein the electromagnetic radiation is scanned across the transition metal dichalcogenide material at a rate of from 0.1 micron per second to 10 microns per second; wherein the electromagnetic radiation is scanned across the transition metal dichalcogenide material for a total amount of time of from 1 second to 10 minutes; or a combination thereof.

39-44. (canceled)

45. The method of claim 1, wherein the transition metal dichalcogenide material has an area in the plane of the surface of the substrate and the thickness of the transition metal dichalcogenide material is decreased to a monolayer over the entire area of the transition metal dichalcogenide material in the plane of the surface of the substrate.

46. The method of claim 1, further comprising removing the thinned transition metal dichalcogenide material from the substrate, thereby creating a free-standing thinned transition metal dichalcogenide material.

47. (canceled)

48. A patterned transition metal dichalcogenide material made using the method of claim 1.

49. A monolayer of a transition metal dichalcogenide made using the method of claim 1.

50-53. (canceled)

54. A system for thinning a transition metal dichalcogenide material, the system comprising:
a substrate having a surface;
a transition metal dichalcogenide material, a source electrode, and aqueous solution disposed on the surface of the substrate;
wherein the source electrode is in electrical contact with the transition metal dichalcogenide material;
wherein the transition metal dichalcogenide material and the source electrode are both submerged in the aqueous solution;
a gate electrode in electrochemical contact with the aqueous solution, wherein the gate electrode is not in physical contact with the transition metal dichalcogenide material;
a power source connected to the source electrode and the gate electrode, wherein the power source is configured to apply a positive potential between the source electrode and the gate electrode, thereby applying a positive potential between the transition metal dichalcogenide material and the gate electrode;
an electromagnetic radiation source configured to illuminate a first location of the transition metal dichalcogenide material with electromagnetic radiation;
wherein the transition metal dichalcogenide material has a thickness at the first location that is greater than a monolayer;
wherein:
when the thickness of the transition metal dichalcogenide material at a location is a monolayer, then the transition metal dichalcogenide material has a direct band gap; and
when the thickness of the transition metal dichalcogenide material at the location is greater than a monolayer, then the transition metal dichalcogenide material has an indirect bandgap;
wherein the indirect band gap has an energy that is the difference between a valence band and a conduction band;
wherein the direct band gap has an energy that is the difference between a valence band and a conduction band;
wherein the indirect band gap is lower in energy than the direct band gap; and
wherein the electromagnetic radiation has an energy that is less than the energy of the direct band gap and greater than or equal to the energy of the indirect band gap;
such that when the first location of the transition metal dichalcogenide material is illuminated with the electromagnetic radiation from the electromagnetic radiation source while the power source applies the positive potential between the transition metal dichalcogenide material and the gate electrode, then:
electrons are promoted from the valence band to the conduction band of the indirect band gap and the thickness of the transition metal dichalcogenide at the first location is decreased via electrochemical degradation, thereby thinning the transition metal dichalcogenide at the first location;
wherein the thinning is self-limiting as the electrochemical degradation ceases when the thickness of the transition metal dichalcogenide at the first location is decreased to a monolayer, because the energy of the electromagnetic energy is insufficient to promote electrons from the valence band to the conduction band of the direct band gap.

55. (canceled)

56. The system of claim 54, further comprising a lens wherein the system is configured such that the electromagnetic radiation from the electromagnetic radiation source traverses the lens and the substrate to illuminate the first location of the transition metal dichalcogenide material.

57. (canceled)

58. (canceled)

59. The system of claim 54, wherein the system further comprises an inverted microscope having a stage, and the substrate is mounted on the stage of the inverted microscope.

60-102. (canceled)
